(19) United States
(12) Patent Application Publication
(10) Pub. No.: US 2025/0260367 A1
(43) Pub. Date: Aug. 14, 2025

(54) TRACKER CIRCUIT

(71) Applicant: Murata Manufacturing Co., Ltd., Nagaokakyo-shi (JP)

(72) Inventors: John R. Hoversten, Waltham, MA (US); David J. Perreault, Waltham, MA (US); Tomoaki Sato, Waltham, MA (US); Muneharu Kato, Nagaokakyo-shi (JP); Takeshi Kogure, Nagaokakyo-shi (JP); Kenzou Oomori, Nagaokakyo-shi (JP)

(21) Appl. No.: 19/195,953

(22) Filed: May 1, 2025

Related U.S. Application Data
(63) Continuation of application No. PCT/JP2023/038426, filed on Oct. 25, 2023.
(60) Provisional application No. 63/423,096, filed on Nov. 7, 2022.

(51) Int. Cl. H03F 1/02; H03F 3/24; H03F 3/72

(52) U.S. Cl. CPC H03F 1/0227; H03F 3/245; H03F 3/72; H03F 2200/102; H03F 2200/105; H03F 2200/372; H03F 2203/7209

(57) ABSTRACT

A tracker circuit is provided that includes a supply modulator to selectively output at least one of a plurality of discrete voltages to a power amplifier, and a filter circuit connected between the supply modulator and the power amplifier. The filter circuit includes an inductor connected between the supply modulator and the power amplifier, a capacitor connected between ground and a path connecting the inductor and the power amplifier, and a switch connected between the supply modulator and the power amplifier without via the inductor.

### CROSS REFERENCE TO RELATED APPLICATIONS

This application is a continuation of International Application No. PCT/JP2023/038426, filed Oct. 25, 2023, which claims priority to U.S. Provisional Patent Application No. 63/423,096, filed Nov. 7, 2022, the entire contents of each of which are hereby incorporated by reference.

### TECHNICAL FIELD

The present disclosure relates to a tracker circuit.

### BACKGROUND

In recent years, tracking techniques have been applied to power amplifier (PA) circuits to improve power-added efficiency. U.S. Pat. No. 8,829,993 discloses a tracker circuit for digital envelope tracking (ET) of supplying a power supply voltage that changes with time to a plurality of discrete levels (hereinafter referred to as a plurality of discrete voltages). U.S. Pat. No. 10,686,407 discloses a tracker circuit for symbol power tracking (SPT) of supplying a plurality of discrete voltages.

In such a tracker circuit that supplies a plurality of discrete voltages, a filter circuit such as a pulse shaping filter or a transition shaping filter may be used to attenuate noise included in the plurality of discrete voltages (see, for example, Patent Document 1).

In the related art, however, it may be difficult to sufficiently attenuate noise included in a plurality of discrete voltages.

### SUMMARY OF THE INVENTION

Accordingly, the exemplary aspects of the present disclosure provide a tracker circuit configured to attenuate noise included in a plurality of discrete voltages.

A tracker circuit according to an exemplary aspect of the present disclosure includes a supply modulator configured to selectively output at least one of a plurality of discrete voltages to a power amplifier, and a filter circuit connected between the supply modulator and the power amplifier. The filter circuit includes a first inductor connected between the supply modulator and the power amplifier, a first capacitor connected between ground and a path connecting the first inductor and the power amplifier, and a first switch connected between the supply modulator and the power amplifier without via the first inductor.

A tracker circuit according to another exemplary aspect of the present disclosure includes an external connection terminal connected to a power amplifier, a supply modulator configured to selectively output at least one of a plurality of discrete voltages to the external connection terminal, and a filter circuit connected between the supply modulator and the external connection terminal. The filter circuit includes a first inductor connected between the supply modulator and the external connection terminal, a first capacitor connected between ground and a path connecting the first inductor and the external connection terminal, and a first switch connected between the supply modulator and the external connection terminal. The first switch has one terminal connected to one end of the first inductor, and has an other terminal connected to an other end of the first inductor.

A tracker circuit according to an exemplary aspect of the present disclosure is provided that is configured to attenuate noise included in a plurality of discrete voltages.

### BRIEF DESCRIPTION OF DRAWINGS

FIG. 1A is a graph illustrating an example of transition of a power supply voltage in an average power tracking (APT) mode.

FIG. 1B is a graph illustrating an example of transition of a power supply voltage in an analog envelope tracking (ET) mode.

FIG. 1C is a graph illustrating an example of transition of a power supply voltage in a digital ET mode.

FIG. 2 is a circuit configuration diagram of a communication device according to a first exemplary embodiment.

FIG. 3 is a circuit configuration diagram of a pre-regulator circuit, a switched-capacitor circuit, and a supply modulator according to the first exemplary embodiment.

FIG. 4 is a circuit configuration diagram of a filter circuit according to a first aspect of the first exemplary embodiment.

FIG. 5 is a circuit configuration diagram of a filter circuit according to a second aspect of the first exemplary embodiment.

FIG. 6 is a circuit configuration diagram of a filter circuit according to a third aspect of the first exemplary embodiment.

FIG. 7 is a circuit configuration diagram of a filter circuit according to a fourth aspect of the first exemplary embodiment.

FIG. 8 is a circuit configuration diagram of a digital control circuit according to the first exemplary embodiment.

FIG. 9 is a plan view of a tracker module according to the first exemplary embodiment.

FIG. 10 is a plan view of the tracker module according to the first exemplary embodiment.

FIG. 11 is a sectional view of the tracker module according to the first exemplary embodiment.

FIG. 12 is a circuit configuration diagram of a communication device according to a second exemplary embodiment.

FIG. 13 is a circuit configuration diagram of a communication device according to a third exemplary embodiment.

FIG. 14 is a circuit configuration diagram of a communication device according to a fourth exemplary embodiment.

FIG. 15 is a circuit configuration diagram of a filter circuit according to the fourth exemplary embodiment.

### DETAILED DESCRIPTION OF EMBODIMENTS

In general, when a plurality of discrete voltages are supplied to a power amplifier (PA), discrete changes in the voltage level increase noise. The increase in noise is remarkable particularly when a digital envelope tracking (ET) mode or the like, in which the voltage level changes discretely and rapidly, is used.

Thus, when a radio frequency (RF) signal amplified by a PA is a transmission signal of a frequency division duplex (FDD) band, a filter for attenuating noise of a difference frequency between a transmission channel frequency and a reception channel frequency may be used in order to prevent intermodulation distortion (TIMD) between noise and the transmission signal (for example, a distortion component generated in a frequency obtained by adding the frequency of noise to the frequency of the transmission signal) from interfering with a reception signal. In this case, the difference frequency between the transmission channel frequency and the reception channel frequency varies according to an FDD band, and thus a switch for switching between filters may be used to cope with a plurality of FDD bands.

However, the inventors have found an issue that the switch may degrade the characteristics of a filter. Specifically, the inventors have found that the Q value (i.e., the quality factor) of a filter is degraded when the switch is connected between a voltage supply path and an LC series circuit that is connected in shunt to the voltage supply path.

Accordingly, exemplary embodiments are provided below for a tracker circuit that is configured to effectively attenuate noise included in a plurality of discrete voltages by suppressing degradation of filter characteristics resulting from a switch. The embodiments described below each illustrate a general or specific example. The numerical values, shapes, materials, constituent elements, the disposition and connection manner of the constituent elements, and so forth described in the following exemplary embodiments are merely examples, and are not intended to limit the exemplary aspects of the present disclosure.

It is noted that the drawings are schematic diagrams drawn with emphasis, omission, or ratio adjustment performed as appropriate in order to illustrate the exemplary embodiments of the present disclosure. It is noted that the illustration therein is not necessarily strict, and may be different from actual shapes, positional relationships, and ratios. In the drawings, constituent elements that are substantially the same are denoted by the same reference numerals, and a repeated description thereof may be omitted or simplified.

In the drawings referred to below and for purposes of this disclosure, an x-axis and a y-axis are axes orthogonal to each other on a plane parallel to main surfaces of a module laminate. Specifically, when the module laminate has a rectangular shape in plan view, the x-axis is parallel to a first side of the module laminate, and the y-axis is parallel to a second side orthogonal to the first side of the module laminate. A z-axis is an axis perpendicular to the main surfaces of the module laminate. The positive direction thereof indicates an upward direction, and the negative direction thereof indicates a downward direction.

In the circuit configurations of the present disclosure, it is noted that the term “connected” includes not only a direct connection using a connection terminal and/or a wiring conductor, but also an electrical connection via another circuit element. Moreover, the term “directly connected” can be used to indicate directly connected using a connection terminal and/or a wiring conductor without interposing another circuit element. “Connected between A and B” can indicate connected to both A and B between A and B, and can indicate connected in series to a path connecting A and B. The “path connecting A and B” can indicate a path composed of a conductor that electrically connects A to B. “Connected in series to a path” can indicate connected between one end of the path and the other end of the path. “Connected in shunt to a path” can indicate connected between the path and ground.

Regarding the disposition of components in the exemplary embodiments, the phrase “a component is disposed on or in a substrate” includes that the component is disposed on a main surface of the substrate and that the component is disposed in the substrate. Moreover, the phrase “a component is disposed on a main surface of a substrate” includes not only that the component is disposed in contact with the main surface of the substrate but also that the component is disposed above the main surface without being in contact with the main surface (for example, the component is stacked on another component disposed in contact with the main surface). In addition, “a component is disposed on a main surface of a substrate” may include that the component is disposed in a recessed portion formed in the main surface. Moreover, the phrase “a component is disposed in a substrate” includes not only that the component is encapsulated in the module laminate but also that the entire component is disposed between both main surfaces of the substrate but part of the component is not covered with the substrate, and that only part of the component is disposed in the substrate.

Regarding the disposition of components in the exemplary embodiments and for purposes of this disclosure, the phrase “in plan view of a module laminate” can indicate that an object that is orthogonally projected and viewed on an xy plane from the positive side of the z-axis. Moreover, the phrase “Aa overlaps B in plan view” can indicate that at least part of the region of A orthogonally projected on the xy plane overlaps at least part of the region of B orthogonally projected on the xy plane. The phrase “A is disposed between B and C” can indicate that at least one of a plurality of line segments connecting a certain point in B and a certain point in C passes through A.

Regarding the disposition of components in the exemplary embodiments and for purposes of this disclosure, the phrase “A is disposed adjacent to B” can indicate that A and B are disposed close to each other, and specifically that there is no other circuit component in a space where A faces B. In other words, “A is disposed adjacent to B” can indicate that none of a plurality of line segments extending to B from a certain point on a surface of A facing B in a normal direction of the surface passes through a circuit component other than A and B. Here, the circuit component can refer to a component including an active element and/or a passive element. That is, the circuit component includes an active component including a transistor, a diode, or the like, and a passive component including an inductor, a transformer, a capacitor, a resistor, or the like, and does not include an electromechanical component including a terminal, a connector, a wiring line, or the like.

In the exemplary aspects of the present disclosure, the term “terminal” can refer to a point at which a conductor in an element terminates. In a case where the impedance of a conductor between elements is sufficiently low, a terminal is interpreted as not only a single point but also any point on the conductor between the elements or the entire conductor.

In addition, for purposes of this disclosure, terms indicating the relationships between elements, such as “parallel” and “perpendicular”, terms indicating the shapes of elements, such as “rectangular”, and numerical ranges do not represent only strict meanings, but include substantially equivalent ranges, for example, an error of about several percent.

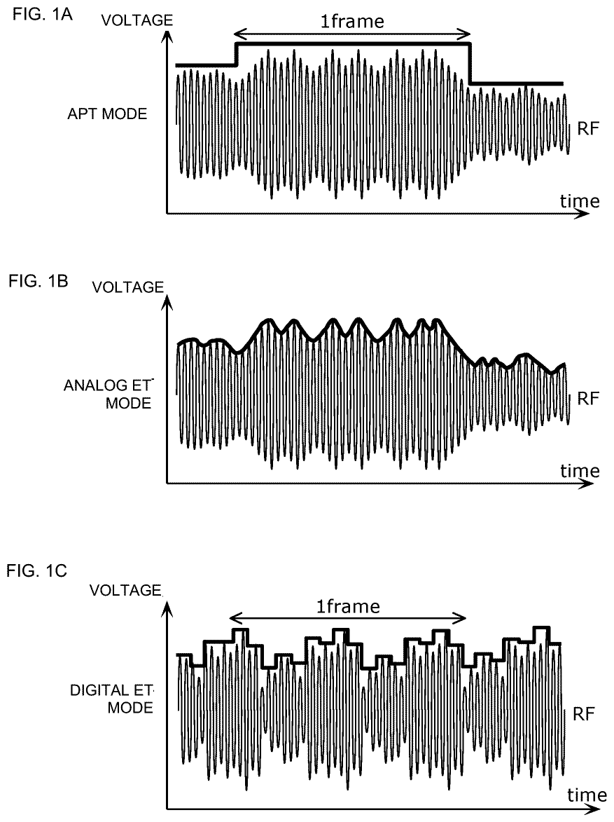

Now, a description will be given of tracking modes of supplying a PA with a power supply voltage dynamically regulated on the basis of an RF signal over time, which are techniques of amplifying the RF signal with high efficiency. In general, a tracking mode is a mode of dynamically regulating the power supply voltage to be applied to a PA. Among several types of tracking modes, an average power tracking (APT) mode and an ET mode (including an analog ET mode and a digital ET mode) will be described with reference to FIG. 1A to FIG. 1C. In FIG. 1A to FIG. 1C, the horizontal axis represents time, and the vertical axis represents voltage. A thick solid line represents a power supply voltage, and a thin solid line (e.g., a waveform) represents a modulated signal.

FIG. 1A is a graph illustrating an example of transition of a power supply voltage in the APT mode. In the APT mode, the power supply voltage is varied to a plurality of discrete voltage levels in units of one frame on the basis of an average power. As a result, the power supply voltage signal forms a rectangular wave.

For purposes of this disclosure, a frame can refer to a unit forming an RF signal (e.g., a modulated signal). For example, in 5th Generation New Radio (5G NR) and Long Term Evolution (LTE), a frame can include ten subframes, each subframe includes a plurality of slots, and each slot is formed by a plurality of symbols. The subframe has a length of 1 ms, and the frame has a length of 10 ms.

According to an exemplary aspect, a mode of varying a voltage level in units of one frame or in larger units on the basis of an average power is referred to as an APT mode, which is distinguished from a mode of varying a voltage level in units smaller than one frame (for example, in units of subframes, slots, or symbols). For example, a mode of varying a voltage level in units of symbols is referred to as a symbol power tracking (SPT) mode, which is distinguished from the APT mode.

FIG. 1B is a graph illustrating an example of transition of a power supply voltage in the analog ET mode. In the analog ET mode, the power supply voltage is continuously varied on the basis of an envelope signal, and thus the envelope of a modulated signal is tracked.

The envelope signal is a signal indicating the envelope of a modulated signal. An envelope value is represented by, for example, the square root of (I²+Q²). (I, Q) represents a constellation point herein. The constellation point is a point representing, on a constellation diagram, a signal modulated by digital modulation. (I, Q) is determined, for example, by a baseband integrated circuit (BBIC), for example, on the basis of transmission information.

FIG. 1C is a graph illustrating an example of transition of a power supply voltage in the digital ET mode. In the digital ET mode, the power supply voltage is varied to a plurality of discrete voltage levels within one frame on the basis of an envelope signal, and thus the envelope of a modulated signal is tracked. As a result, the power supply voltage signal forms a rectangular wave.

### First Exemplary Embodiment

Hereinafter, a first exemplary embodiment will be described. A communication device 7 according to the present embodiment corresponds to user equipment (UE) in a cellular network, and is typically a mobile phone, a smartphone, a tablet computer, a wearable device, or the like. The communication device 7 may be an Internet of Things (IoT) sensor device, a medical/health-care device, a vehicle, an unmanned aerial vehicle (UAV) (a so-called drone), or an automated guided vehicle (AGV). The communication device 7 can be configured to function as a base station (BS) in a cellular network.

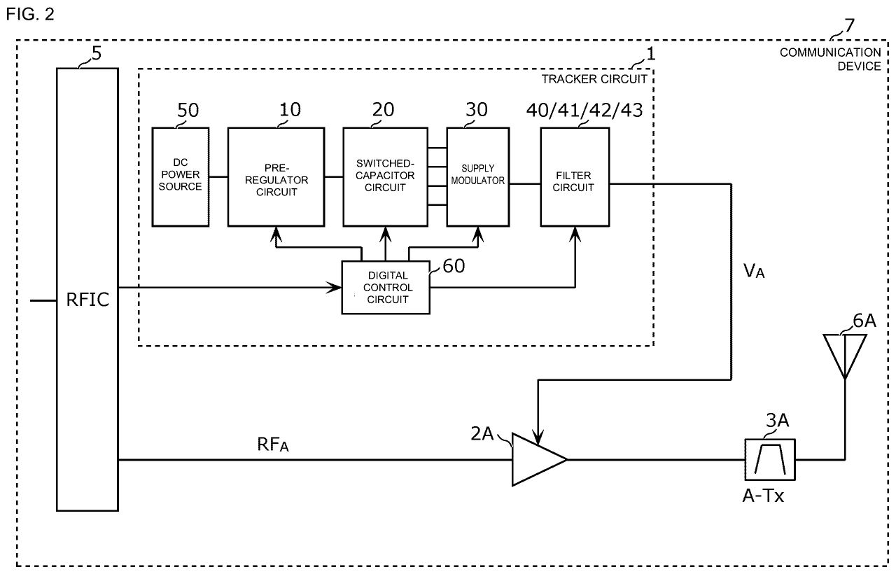

The circuit configuration of the communication device 7 and a tracker circuit 1 according to the present embodiment will be described with reference to FIG. 2. FIG. 2 is a circuit configuration diagram of the communication device 7 according to the present embodiment.

FIG. 2 illustrates an exemplary circuit configuration. The communication device 7 and the tracker circuit 1 may be packaged by using any of a wide variety of circuit packaging methods and circuit techniques. Thus, the description of the communication device 7 and the tracker circuit 1 provided below should not be so limited according to the exemplary aspects.

### [1.1 Circuit Configuration of Communication Device 7]

First, the communication device 7 according to the present embodiment will be described with reference to FIG. 2. The communication device 7 includes the tracker circuit 1, a power amplifier (PA) 2A, a filter 3A, a radio frequency integrated circuit (RFIC) 5, and an antenna 6A.

The tracker circuit 1 is configured to supply a plurality of discrete voltages V_{A} to the PA 2A on the basis of a tracking mode. The tracking mode may be, but is not limited to, the digital ET mode or the SPT mode. As illustrated in FIG. 2, the tracker circuit 1 includes a pre-regulator circuit 10, a switched-capacitor circuit 20, a supply modulator 30, any one of filter circuits 40 to 43, a direct current (DC) power source 50, and a digital control circuit 60.

The pre-regulator circuit 10 includes a power inductor and a switch. The power inductor is an inductor used to raise and/or lower a DC voltage. The power inductor is connected in series to a DC path. Alternatively, the power inductor may be connected between the DC path and ground (disposed in parallel). The pre-regulator circuit 10 is configured to convert an input voltage into a first voltage by using the power inductor. According to an exemplary aspect, a pre-regulator circuit 10 may also be referred to as a magnetic regulator or a DC-DC converter.

The switched-capacitor circuit 20 includes a plurality of capacitors and a plurality of switches, and is configured to generate, from the first voltage received from the pre-regulator circuit 10, a plurality of second voltages each having a corresponding one of a plurality of discrete voltage levels, as a plurality of discrete voltages. According to an exemplary aspect, the switched-capacitor circuit 20 may also be referred to as a switched-capacitor voltage balancer.

The supply modulator 30 is configured to selectively output at least one of the plurality of second voltages generated by the switched-capacitor circuit 20 to the PA 2A. The supply modulator 30 is controlled on the basis of a digital control signal.

The filter circuits 40 to 43 are configured to attenuate noise from a plurality of discrete voltages that are to be supplied to the PA 2A. According to an exemplary aspect, the filter circuits 40 to 43 may also be referred to as pulse shaping filters or transition shaping filters.

The DC power source 50 is configured to supply a DC voltage to the pre-regulator circuit 10. The DC power source 50 may be, but is not limited to, a rechargeable battery, for example.

The digital control circuit 60 is configured to control the pre-regulator circuit 10, the switched-capacitor circuit 20, the supply modulator 30, and any one of the filter circuits 40 to 43 on the basis of digital control signals from the RFIC 5.

It is noted that the tracker circuit 1 can omit at least one of the pre-regulator circuit 10, the switched-capacitor circuit 20, the supply modulator 30, any one of the filter circuits 40 to 43, the DC power source 50, or the digital control circuit 60 in exemplary aspects. For example, the tracker circuit 1 need not necessarily include the DC power source 50. Any combination of the pre-regulator circuit 10, the switched-capacitor circuit 20, the supply modulator 30, and any one of the filter circuits 40 to 43 may be integrated into a single circuit. The tracker circuit 1 may include, like Patent Document 2, a plurality of voltage supply circuits instead of the pre-regulator circuit 10 and the switched-capacitor circuit 20. In this case, the supply modulator 30 may be configured to select at least one of the plurality of voltage supply circuits.

The PA 2A is connected between the RFIC 5 and the filter 3A. The PA 2A is further connected to the tracker circuit 1. The PA 2A is configured to amplify an RF signal RF_{A} of band A received from the RFIC 5, by using the plurality of discrete voltages V_{A} received from the tracker circuit 1.

The filter 3A is connected between the PA 2A and the antenna 6A. The filter 3A is a band pass filter having a pass band including band A.

Band A is a frequency band for a communication system constructed by using radio access technology (RAT), and is predefined by standardizing bodies (for example, 3rd Generation Partnership Project (3GPP, registered trademark), Institute of Electrical and Electronics Engineers (IEEE), and so forth). Examples of the communication system include a 5th Generation New Radio (5G NR) system, a Long Term Evolution (LTE) system, and a Wireless Local Area Network (WLAN) system.

In an exemplary aspect, the RFIC 5 can be an example of a signal processing circuit configured to process an RF signal. Specifically, the RFIC 5 performs signal processing such as up-conversion on a transmission signal input thereto and supplies an RF transmission signal generated through the signal processing to the PA 2A. The RFIC 5 includes a control unit that controls the tracker circuit 1. Some or all of the functions of the control unit of the RFIC 5 may be implemented outside the RFIC 5.

The antenna 6A are configured to output a transmission signal of band A received from the PA 2A through the filter 3A. It should be appreciated that the antenna 6A need not necessarily be included in the communication device 7 in an exemplary aspect.

The circuit configuration of the communication device 7 illustrated in FIG. 2 is illustrative and is not restrictive. For example, the communication device 7 may include a baseband signal processing circuit that performs signal processing by using an intermediate frequency band lower than the frequency of the RF signal RF_{A}.

### [1.2 Circuit Configuration of Tracker Circuit 1]

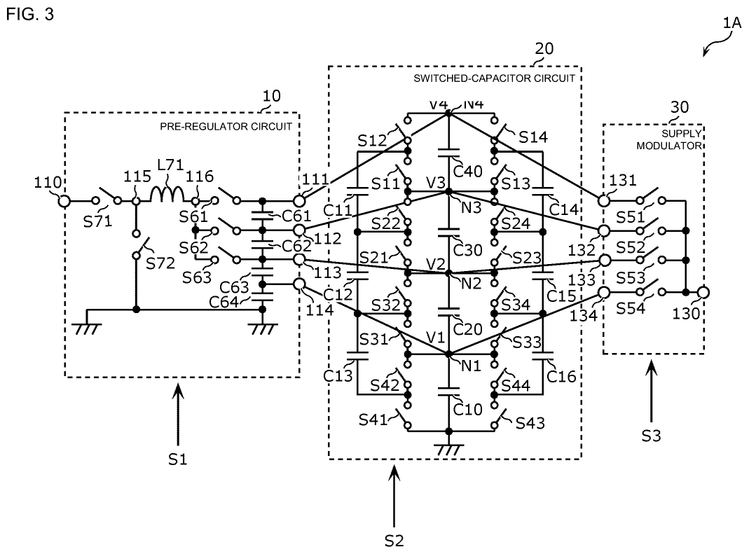

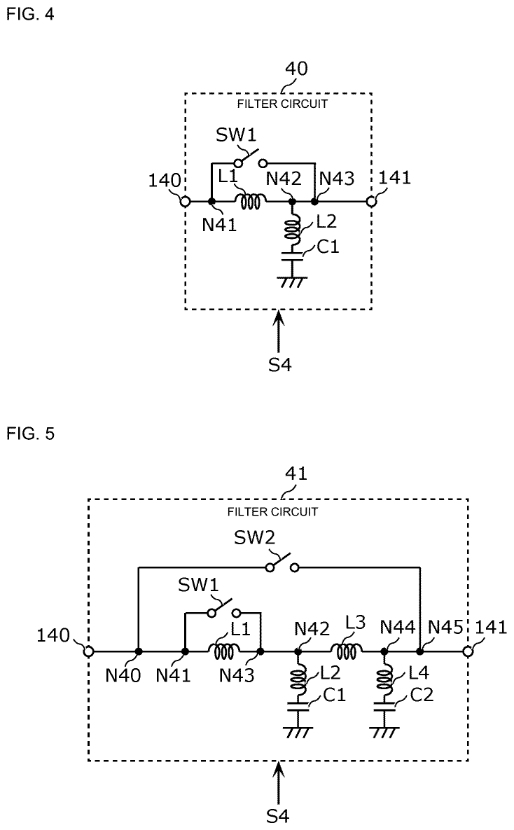

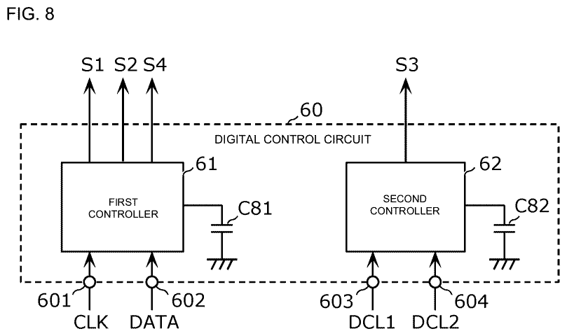

Next, the circuit configurations of the pre-regulator circuit 10, the switched-capacitor circuit 20, the supply modulator 30, the filter circuits 40 to 43, and the digital control circuit 60 included in the tracker circuit 1 will be described with reference to FIG. 3 to FIG. 8. FIG. 3 is a circuit configuration diagram of the pre-regulator circuit 10, the switched-capacitor circuit 20, and the supply modulator 30 according to the present embodiment. FIG. 4 to FIG. 7 are circuit configuration diagrams of the filter circuits 40 to 43 according to a first aspect to a fourth aspect of the present embodiment. FIG. 8 is a circuit configuration diagram of the digital control circuit 60 according to the present embodiment.

FIG. 3 to FIG. 8 each illustrate an exemplary circuit configuration. The pre-regulator circuit 10, the switched-capacitor circuit 20, the supply modulator 30, the filter circuits 40 to 43, and the digital control circuit 60 may be packaged by using any of a wide variety of circuit packaging methods and circuit techniques. Thus, the description of the individual circuits provided below should not be so limited according to the exemplary aspects.

### [1.2.1 Circuit Configuration of Switched-Capacitor Circuit 20]

First, the circuit configuration of the switched-capacitor circuit 20 will be described with reference to FIG. 3. As illustrated in FIG. 3, the switched-capacitor circuit 20 includes capacitors C11 to C16, capacitors C10, C20, C30, and C40, and switches S11 to S14, S21 to S24, S31 to S34, and S41 to S44. Energy and electric charge are input from the pre-regulator circuit 10 to the switched-capacitor circuit 20 at nodes N1 to N4 and output from the switched-capacitor circuit 20 to the supply modulator 30 at the nodes N1 to N4.

In an exemplary aspect, the capacitors C11 to C16 are each configured to function as a flying capacitor (also referred to as a “transfer capacitor”). Specifically, the capacitors C11 to C16 are each used to raise or lower the first voltage supplied from the pre-regulator circuit 10. More specifically, the capacitors C11 to C16 cause electric charges to move between the capacitors C11 to C16 and the nodes N1 to N4 so that voltages V1 to V4 (e.g., voltages with respect to a ground potential) satisfying V1:V2:V3:V4=1:2:3:4 are maintained at the four nodes N1 to N4. The voltages V1 to V4 correspond to the plurality of second voltages each having a corresponding one of a plurality of discrete voltage levels.

The capacitor C11 has two electrodes. One of the two electrodes of the capacitor C11 is connected to one terminal of the switch S11 and one terminal of the switch S12. The other of the two electrodes of the capacitor C11 is connected to one terminal of the switch S21 and one terminal of the switch S22.

The capacitor C12 has two electrodes. One of the two electrodes of the capacitor C12 is connected to the one terminal of the switch S21 and the one terminal of the switch S22. The other of the two electrodes of the capacitor C12 is connected to one terminal of the switch S31 and one terminal of the switch S32.

The capacitor C13 has two electrodes. One of the two electrodes of the capacitor C13 is connected to the one terminal of the switch S31 and the one terminal of the switch S32. The other of the two electrodes of the capacitor C13 is connected to one terminal of the switch S41 and one terminal of the switch S42.

The capacitor C14 has two electrodes. One of the two electrodes of the capacitor C14 is connected to one terminal of the switch S13 and one terminal of the switch S14. The other of the two electrodes of the capacitor C14 is connected to one terminal of the switch S23 and one terminal of the switch S24.

The capacitor C15 has two electrodes. One of the two electrodes of the capacitor C15 is connected to the one terminal of the switch S23 and the one terminal of the switch S24. The other of the two electrodes of the capacitor C15 is connected to one terminal of the switch S33 and one terminal of the switch S34.

The capacitor C16 has two electrodes. One of the two electrodes of the capacitor C16 is connected to the one terminal of the switch S33 and the one terminal of the switch S34. The other of the two electrodes of the capacitor C16 is connected to one terminal of the switch S43 and one terminal of the switch S44.

A set of the capacitors C11 and C14, a set of the capacitors C12 and C15, and a set of the capacitors C13 and C16 can each be charged and discharged in a complementary manner as a result of a first phase and a second phase being repeated.

Specifically, in the first phase, the switches S12, S13, S22, S23, S32, S33, S42, and S43 are turned ON. Accordingly, for example, the one of the two electrodes of the capacitor C12 is connected to the node N3, the other of the two electrodes of the capacitor C12 and the one of the two electrodes of the capacitor C15 are connected to the node N2, and the other of the two electrodes of the capacitor C15 is connected to the node N1.

On the other hand, in the second phase, the switches S11, S14, S21, S24, S31, S34, S41, and S44 are turned ON. Accordingly, for example, the one of the two electrodes of the capacitor C15 is connected to the node N3, the other of the two electrodes of the capacitor C15 and the one of the two electrodes of the capacitor C12 are connected to the node N2, and the other of the two electrodes of the capacitor C12 is connected to the node N1.

As a result of the first phase and the second phase being repeated, for example, when one of the capacitors C12 and C15 is charged through the node N2, the other of the capacitors C12 and C15 can be discharged to the capacitor C30. In short, the capacitors C12 and C15 can be charged and discharged in a complementary manner.

Similarly to the set of the capacitors C12 and C15, the set of the capacitors C11 and C14 and the set of the capacitors C13 and C16 can each be charged and discharged in a complementary manner as a result of the first phase and the second phase being repeated.

The capacitors C10, C20, C30, and C40 can each be configured to function as a smoothing capacitor in an exemplary aspect. Specifically, the capacitors C10, C20, C30, and C40 are used to hold and smooth the voltages V1 to V4 at the nodes N1 to N4, respectively.

The capacitor C10 is connected between the node N1 and ground. Specifically, one of the two electrodes of the capacitor C10 is connected to the node N1. On the other hand, the other of the two electrodes of the capacitor C10 is connected to ground.

The capacitor C20 is connected between the nodes N2 and N1. Specifically, one of the two electrodes of the capacitor C20 is connected to the node N2. On the other hand, the other of the two electrodes of the capacitor C20 is connected to the node N1.

The capacitor C30 is connected between the nodes N3 and N2. Specifically, one of the two electrodes of the capacitor C30 is connected to the node N3. On the other hand, the other of the two electrodes of the capacitor C30 is connected to the node N2.

The capacitor C40 is connected between the nodes N4 and N3. Specifically, one of the two electrodes of the capacitor C40 is connected to the node N4. On the other hand, the other of the two electrodes of the capacitor C40 is connected to the node N3.

The switch S11 is connected between the one of the two electrodes of the capacitor C11 and the node N3. Specifically, the one terminal of the switch S11 is connected to the one of the two electrodes of the capacitor C11. On the other hand, the other terminal of the switch S11 is connected to the node N3.

The switch S12 is connected between the one of the two electrodes of the capacitor C11 and the node N4. Specifically, the one terminal of the switch S12 is connected to the one of the two electrodes of the capacitor C11. On the other hand, the other terminal of the switch S12 is connected to the node N4.

The switch S21 is connected between the one of the two electrodes of the capacitor C12 and the node N2. Specifically, the one terminal of the switch S21 is connected to the one of the two electrodes of the capacitor C12 and the other of the two electrodes of the capacitor C11. On the other hand, the other terminal of the switch S21 is connected to the node N2.

The switch S22 is connected between the one of the two electrodes of the capacitor C12 and the node N3. Specifically, the one terminal of the switch S22 is connected to the one of the two electrodes of the capacitor C12 and the other of the two electrodes of the capacitor C11. On the other hand, the other terminal of the switch S22 is connected to the node N3.

The switch S31 is connected between the other of the two electrodes of the capacitor C12 and the node N1. Specifically, the one terminal of the switch S31 is connected to the other of the two electrodes of the capacitor C12 and the one of the two electrodes of the capacitor C13. On the other hand, the other terminal of the switch S31 is connected to the node N1.

The switch S32 is connected between the other of the two electrodes of the capacitor C12 and the node N2. Specifically, the one terminal of the switch S32 is connected to the other of the two electrodes of the capacitor C12 and the one of the two electrodes of the capacitor C13. On the other hand, the other terminal of the switch S32 is connected to the node N2. That is, the other terminal of the switch S32 is connected to the other terminal of the switch S21.

The switch S41 is connected between the other of the two electrodes of the capacitor C13 and ground. Specifically, the one terminal of the switch S41 is connected to the other of the two electrodes of the capacitor C13. On the other hand, the other terminal of the switch S41 is connected to ground.

The switch S42 is connected between the other of the two electrodes of the capacitor C13 and the node N1. Specifically, the one terminal of the switch S42 is connected to the other of the two electrodes of the capacitor C13. On the other hand, the other terminal of the switch S42 is connected to the node N1. That is, the other terminal of the switch S42 is connected to the other terminal of the switch S31.

The switch S13 is connected between the one of the two electrodes of the capacitor C14 and the node N3. Specifically, the one terminal of the switch S13 is connected to the one of the two electrodes of the capacitor C14. On the other hand, the other terminal of the switch S13 is connected to the node N3. That is, the other terminal of the switch S13 is connected to the other terminal of the switch S11 and the other terminal of the switch S22.

The switch S14 is connected between the one of the two electrodes of the capacitor C14 and the node N4. Specifically, the one terminal of the switch S14 is connected to the one of the two electrodes of the capacitor C14. On the other hand, the other terminal of the switch S14 is connected to the node N4. That is, the other terminal of the switch S14 is connected to the other terminal of the switch S12.

The switch S23 is connected between the one of the two electrodes of the capacitor C15 and the node N2. Specifically, the one terminal of the switch S23 is connected to the one of the two electrodes of the capacitor C15 and the other of the two electrodes of the capacitor C14. On the other hand, the other terminal of the switch S23 is connected to the node N2. That is, the other terminal of the switch S23 is connected to the other terminal of the switch S21 and the other terminal of the switch S32.

The switch S24 is connected between the one of the two electrodes of the capacitor C15 and the node N3. Specifically, the one terminal of the switch S24 is connected to the one of the two electrodes of the capacitor C15 and the other of the two electrodes of the capacitor C14. On the other hand, the other terminal of the switch S24 is connected to the node N3. That is, the other terminal of the switch S24 is connected to the other terminal of the switch S11, the other terminal of the switch S22, and the other terminal of the switch S13.

The switch S33 is connected between the other of the two electrodes of the capacitor C15 and the node N1. Specifically, the one terminal of the switch S33 is connected to the other of the two electrodes of the capacitor C15 and the one of the two electrodes of the capacitor C16. On the other hand, the other terminal of the switch S33 is connected to the node N1. That is, the other terminal of the switch S33 is connected to the other terminal of the switch S31 and the other terminal of the switch S42.

The switch S34 is connected between the other of the two electrodes of the capacitor C15 and the node N2. Specifically, the one terminal of the switch S34 is connected to the other of the two electrodes of the capacitor C15 and the one of the two electrodes of the capacitor C16. On the other hand, the other terminal of the switch S34 is connected to the node N2. That is, the other terminal of the switch S34 is connected to the other terminal of the switch S21, the other terminal of the switch S32, and the other terminal of the switch S23.

The switch S43 is connected between the other of the two electrodes of the capacitor C16 and ground. Specifically, the one terminal of the switch S43 is connected to the other of the two electrodes of the capacitor C16. On the other hand, the other terminal of the switch S43 is connected to ground.

The switch S44 is connected between the other of the two electrodes of the capacitor C16 and the node N1. Specifically, the one terminal of the switch S44 is connected to the other of the two electrodes of the capacitor C16. On the other hand, the other terminal of the switch S44 is connected to the node N1. That is, the other terminal of the switch S44 is connected to the other terminal of the switch S31, the other terminal of the switch S42, and the other terminal of the switch S33.

A first set of switches including the switches S12, S13, S22, S23, S32, S33, S42, and S43, and a second set of switches including the switches S11, S14, S21, S24, S31, S34, S41, and S44 are switched between ON and OFF in a complementary manner on the basis of a control signal S2. Specifically, in the first phase, the switches in the first set are turned ON whereas the switches in the second set are turned OFF. Conversely, in the second phase, the switches in the first set are turned OFF whereas the switches in the second set are turned ON.

For example, in one of the first phase and the second phase, charging from the capacitors C11 to C13 to the capacitors C10 to C40 is performed, and in the other of the first phase and the second phase, charging from the capacitors C14 to C16 to the capacitors C10 to C40 is performed. In other words, because the capacitors C10 to C40 are constantly charged by the capacitors C11 to C13 or the capacitors C14 to C16, the nodes N1 to N4 are rapidly replenished with electric charges even when currents rapidly flow from the nodes N1 to N4 to the supply modulator 30. Thus, potential variations at the nodes N1 to N4 can be suppressed.

As a result of operating in the above-described manner, the switched-capacitor circuit 20 is configured to maintain substantially equal voltages across each of the capacitors C10, C20, C30, and C40. Specifically, the voltages V1 to V4 (voltages with respect to a ground potential) satisfying V1:V2:V3:V4=1:2:3:4 are maintained at the four nodes labeled V1 to V4. The voltage levels of the voltages V1 to V4 correspond to a plurality of discrete voltage levels that can be supplied to the supply modulator 30 by the switched-capacitor circuit 20.

It is noted that the voltage ratio V1:V2:V3:V4 is not limited to 1:2:3:4. For example, the voltage ratio V1:V2:V3:V4 may be 1:2:4:8 in another exemplary aspect.

The configuration of the switched-capacitor circuit 20 illustrated in FIG. 3 is illustrative and is not restrictive. In FIG. 3, the switched-capacitor circuit 20 can be configured to supply voltages of four discrete voltage levels, but the configuration is not limited thereto. The switched-capacitor circuit 20 can also be configured to supply voltages of any number of two or more discrete voltage levels. For example, in the case of supplying voltages of two discrete voltage levels, it is sufficient that the switched-capacitor circuit 20 include at least the capacitors C12 and C15 and the switches S21 to S24 and S31 to S34.

### [1.2.2 Circuit Configuration of Supply Modulator 30]

Next, the circuit configuration of the supply modulator 30 will be described with reference to FIG. 3. The supply modulator 30 is connected to the digital control circuit 60. As illustrated in FIG. 3, the supply modulator 30 includes input terminals 131 to 134, switches S51 to S54, and an output terminal 130.

The output terminal 130 is connected to an input terminal 140 of any of the filter circuits 40 to 43. The output terminal 130 is a terminal configured to supply, via any one of the filter circuits 40 to 43, the PA 2A with a power supply voltage selected from among the voltages V1 to V4.

The input terminals 131 to 134 are connected to the nodes N4 to N1 of the switched-capacitor circuit 20, respectively. The input terminals 131 to 134 are terminals for receiving the voltages V4 to V1 from the switched-capacitor circuit 20, respectively.

The switch S51 is connected between the input terminal 131 and the output terminal 130. Specifically, the switch S51 has a terminal connected to the input terminal 131 and a terminal connected to the output terminal 130. In this connection configuration, ON/OFF switching of the switch S51 by a control signal S3 enables switching between connection and disconnection between the input terminal 131 and the output terminal 130.

The switch S52 is connected between the input terminal 132 and the output terminal 130. Specifically, the switch S52 has a terminal connected to the input terminal 132 and a terminal connected to the output terminal 130. In this connection configuration, ON/OFF switching of the switch S52 by the control signal S3 enables switching between connection and disconnection between the input terminal 132 and the output terminal 130.

The switch S53 is connected between the input terminal 133 and the output terminal 130. Specifically, the switch S53 has a terminal connected to the input terminal 133 and a terminal connected to the output terminal 130. In this connection configuration, ON/OFF switching of the switch S53 by the control signal S3 enables switching between connection and disconnection between the input terminal 133 and the output terminal 130.

The switch S54 is connected between the input terminal 134 and the output terminal 130. Specifically, the switch S54 has a terminal connected to the input terminal 134 and a terminal connected to the output terminal 130. In this connection configuration, ON/OFF switching of the switch S54 by the control signal S3 enables switching between connection and disconnection between the input terminal 134 and the output terminal 130.

These switches S51 to S54 are controlled so as to be exclusively turned ON. In other words, only any one of the switches S51 to S54 is turned ON, and the others are turned OFF. Accordingly, the supply modulator 30 is configured to output one voltage selected from among the voltages V1 to V4.

The configuration of the supply modulator 30 illustrated in FIG. 3 is illustrative and is not restrictive. In particular, the switches S51 to S54 may have any configuration as long as at least one of the four input terminals 131 to 134 can be selectively connected to the output terminal 130. For example, the supply modulator 30 may further include a switch connected between a set of the switches S51 to S53 and a set of the switch S54 and the output terminal 130. For example, the supply modulator 30 may further include a switch connected between a set of the switches S51 and S52 and a set of the switches S53 and S54 and the output terminal 130.

In a case where voltages of two discrete voltage levels are supplied from the switched-capacitor circuit 20, it is sufficient that the supply modulator 30 include at least two of the switches S51 to S54.

### [1.2.3 Circuit Configuration of Pre-Regulator Circuit 10]

Next, the configuration of the pre-regulator circuit 10 will be described with reference to FIG. 3. As illustrated in FIG. 3, the pre-regulator circuit 10 includes an input terminal 110, output terminals 111 to 114, inductor connection terminals 115 and 116, switches S61 to S63, S71, and S72, a power inductor L71, and capacitors C61 to C64.

The input terminal 110 is an input terminal for a DC voltage. Specifically, the input terminal 110 is a terminal for receiving an input voltage from the DC power source 50.

The output terminal 111 is an output terminal for the voltage V4. Specifically, the output terminal 111 is a terminal configured to supply the voltage V4 to the switched-capacitor circuit 20. The output terminal 111 is connected to the node N4 of the switched-capacitor circuit 20.

The output terminal 112 is an output terminal for the voltage V3. Specifically, the output terminal 112 is a terminal configured to supply the voltage V3 to the switched-capacitor circuit 20. The output terminal 112 is connected to the node N3 of the switched-capacitor circuit 20.

The output terminal 113 is an output terminal for the voltage V2. Specifically, the output terminal 113 is a terminal configured to supply the voltage V2 to the switched-capacitor circuit 20. The output terminal 113 is connected to the node N2 of the switched-capacitor circuit 20.

The output terminal 114 is an output terminal for the voltage V1. Specifically, the output terminal 114 is a terminal configured to supply the voltage V1 to the switched-capacitor circuit 20. The output terminal 114 is connected to the node N1 of the switched-capacitor circuit 20.

The inductor connection terminal 115 is connected to one end of the power inductor L71. The inductor connection terminal 116 is connected to the other end of the power inductor L71. In general, the term “one end” can refer to a first end and the term “the other end” can refer to a second end of an exemplary component, such as the power inductor L71.

The switch S71 is connected between the input terminal 110 and the one end of the power inductor L71. Specifically, the switch S71 has a terminal connected to the input terminal 110, and a terminal connected to the one end of the power inductor L71 via the inductor connection terminal 115. In this connection configuration, ON/OFF switching of the switch S71 based on a control signal S1 enables switching between connection and disconnection between the input terminal 110 and the one end of the power inductor L71.

The switch S72 is connected between the one end of the power inductor L71 and ground. Specifically, the switch S72 has a terminal connected to the one end of the power inductor L71 via the inductor connection terminal 115, and a terminal connected to ground. In this connection configuration, ON/OFF switching of the switch S72 based on the control signal S1 enables switching between connection and disconnection between the one end of the power inductor L71 and ground.

The switch S61 is connected between the other end of the power inductor L71 and the output terminal 111. Specifically, the switch S61 has a terminal connected to the other end of the power inductor L71 via the inductor connection terminal 116, and a terminal connected to the output terminal 111. In this connection configuration, ON/OFF switching of the switch S61 based on the control signal S1 enables switching between connection and disconnection between the other end of the power inductor L71 and the output terminal 111.

The switch S62 is connected between the other end of the power inductor L71 and the output terminal 112. Specifically, the switch S62 has a terminal connected to the other end of the power inductor L71 via the inductor connection terminal 116, and a terminal connected to the output terminal 112. In this connection configuration, ON/OFF switching of the switch S62 based on the control signal S1 enables switching between connection and disconnection between the other end of the power inductor L71 and the output terminal 112.

The switch S63 is connected between the other end of the power inductor L71 and the output terminal 113. Specifically, the switch S63 has a terminal connected to the other end of the power inductor L71 via the inductor connection terminal 116, and a terminal connected to the output terminal 113. In this connection configuration, ON/OFF switching of the switch S63 based on the control signal S1 enables switching between connection and disconnection between the other end of the power inductor L71 and the output terminal 113.

One of the two electrodes of the capacitor C61 is connected to the switch S61 and the output terminal 111. The other of the two electrodes of the capacitor C61 is connected to the switch S62, the output terminal 112, and one of the two electrodes of the capacitor C62.

The one of the two electrodes of the capacitor C62 is connected to the switch S62, the output terminal 112, and the other of the two electrodes of the capacitor C61. The other of the two electrodes of the capacitor C62 is connected to a path connecting the switch S63, the output terminal 113, and one of the two electrodes of the capacitor C63.

The one of the two electrodes of the capacitor C63 is connected to the switch S63, the output terminal 113, and the other of the two electrodes of the capacitor C62. The other of the two electrodes of the capacitor C63 is connected to the output terminal 114 and one of the two electrodes of the capacitor C64.

The one of the two electrodes of the capacitor C64 is connected to the output terminal 114 and the other of the two electrodes of the capacitor C63. The other of the two electrodes of the capacitor C64 is connected to ground.

The switches S61 to S63 are controlled so as to be exclusively turned ON. In other words, only any one of the switches S61 to S63 is turned ON, and the others are turned OFF. Turning ON of only any one of the switches S61 to S63 enables the pre-regulator circuit 10 to change the voltage to be supplied to the switched-capacitor circuit 20 at the voltage levels of the voltages V2 to V4.

The pre-regulator circuit 10 configured as described above can supply electric charge to the switched-capacitor circuit 20 via at least one of the output terminals 111 to 113.

In a case where an input voltage is converted into one first voltage, it is sufficient that the pre-regulator circuit 10 include at least the switches S71 and S72 and the power inductor L71.

### [1.2.4 Circuit Configuration of Filter Circuit 40]

Next, the circuit configuration of the filter circuit 40 according to the first aspect of the present embodiment will be described with reference to FIG. 4.

As illustrated in FIG. 4, the filter circuit 40 includes inductors L1 and L2, a capacitor C1, a switch SW1, an input terminal 140, and an output terminal 141.

The input terminal 140 is connected to the output terminal 130 of the supply modulator 30. The input terminal 140 is a terminal for receiving a voltage selected by the supply modulator 30 from among a plurality of discrete voltages.

In an exemplary aspect, the output terminal 141 is an external connection terminal of the tracker circuit 1 and is connected to the PA 2A outside the tracker circuit 1. The output terminal 141 is a terminal configured to supply the plurality of discrete voltages V_{A} that have passed through the filter circuit 40 to the PA 2A.

In an exemplary aspect, the inductor L1 is an example of a first inductor and is connected between the input terminal 140 and the output terminal 141. That is, the inductor L1 is connected in series to a path connecting the input terminal 140 and the output terminal 141. Specifically, one end of the inductor L1 is connected to the input terminal 140, and the other end of the inductor L1 is connected to the output terminal 141.

In an exemplary aspect, the inductor L2 is an example of a second inductor and is connected between ground and a path connecting the inductor L1 and the output terminal 141. That is, the inductor L2 is connected in shunt to the path connecting the input terminal 140 and the output terminal 141. Specifically, one end of the inductor L2 is connected to a node N42 on the path connecting the inductor L1 and the output terminal 141, and the other end of the inductor L2 is connected to ground via the capacitor C1. It should be appreciated that the inductor L2 may be connected between the capacitor C1 and ground, and can be omitted from the filter circuit 40.

In an exemplary aspect, the capacitor C1 is an example of a first capacitor and is connected between the inductor L2 and ground. That is, the capacitor C1 is connected in shunt to the path connecting the input terminal 140 and the output terminal 141. Specifically, one end of the capacitor C1 is connected to the inductor L2, and the other end of the capacitor C1 is connected to ground.

In an exemplary aspect, the switch SW1 is an example of a first switch and is connected between the input terminal 140 and the output terminal 141 without via the inductor L1. That is, the switch SW1 is connected in series to a path that bypasses the inductor L1 between the input terminal 140 and the output terminal 141. Specifically, one terminal of the switch SW1 is connected to a node N41 on a path connecting the input terminal 140 and the inductor L1, and the other terminal of the switch SW1 is connected to a node N43 on the path connecting the inductor L1 and the output terminal 141. In general, the term “one terminal” can refer to a first terminal and the term “the other terminal end” can refer to a second terminal of an exemplary component, such as switch SW1, for example.

Although the switch SW1 and the inductor L1 are connected in parallel in FIG. 4, another circuit element may be inserted into the path of the switch SW1 and/or the path of the inductor L1. For example, an inductor may be connected between the switch SW1 and the node N43 and/or between the switch SW1 and the node N41.

In FIG. 4, the node N43 to which the other terminal of the switch SW1 is connected is located between the node N42 to which the inductor L2 is connected and the output terminal 141, but the positional relationship between the nodes N42 and N43 is not limited thereto. For example, the node N42 may be located between the node N43 and the output terminal 141. Alternatively, for example, the position of the node N42 may be the same as the position of the node N43.

The switch SW1 connected in this manner is switched between ON and OFF on the basis of a control signal S4. Accordingly, the filter circuit 40 is configured to switch between ON and OFF of a band elimination filter for removing noise from a plurality of discrete voltages. For example, ON/OFF switching of the band elimination filter is performed by ON/OFF control of the switch SW1 in the following manner.

TABLE 1

| | SW1 |
|---|---|
| (1) No BEF | ON |
| (2) BEF1 | OFF |

Closing of the switch SW1 causes the inductor L2 and the capacitor C1 to be connected to the input terminal 140 without via the inductor L1. Accordingly, the inductor L2 and the capacitor C1 do not function as a band elimination filter (No BEF) in this exemplary aspect.

Opening of the switch SW1 causes the inductor L2 and the capacitor C1 to be connected to the input terminal 140 via the inductor L1. Accordingly, the inductor L2 and the capacitor C1 can be configured to function as a band elimination filter (also referred to as a “notch filter”) (BEF1).

Such ON/OFF of the band elimination filter can be controlled on the basis of, for example, the channel band width (i.e., the modulation band width) of the RF signal RF_{A}. In a case where the PA 2A is configured to amplify transmission signals of a plurality of frequency bands, ON/OFF of the switch SW1 may be controlled on the basis of the frequency band of the transmission signal amplified by the PA 2A. The control of the band elimination filter is not limited to the above.

### [1.2.5 Circuit Configuration of Filter Circuit 41]

Next, the circuit configuration of the filter circuit 41 according to the second aspect of the present embodiment will be described with reference to FIG. 5.

As illustrated in FIG. 5, the filter circuit 41 includes inductors L1 to L4, capacitors C1 and C2, switches SW1 and SW2, an input terminal 140, and an output terminal 141.

In an exemplary aspect, the inductor L3 is an example of a third inductor and is connected between the inductor L1 and the output terminal 141. That is, the inductor L3 is connected in series to a path connecting the input terminal 140 and the output terminal 141. Specifically, one end of the inductor L3 is connected to the inductor L1, and the other end of the inductor L3 is connected to the output terminal 141.

In an exemplary aspect, the inductor L4 is an example of a fourth inductor and is connected between ground and a path connecting the inductor L3 and the output terminal 141. That is, the inductor L4 is connected in shunt to the path connecting the input terminal 140 and the output terminal 141. Specifically, one end of the inductor L4 is connected to a node N44 on the path connecting the inductor L3 and the output terminal 141, and the other end of the inductor L4 is connected to ground via the capacitor C2. It should be appreciated that the inductor L4 may be connected between the capacitor C2 and ground and need not necessarily be included in the filter circuit 41.

In an exemplary aspect, the capacitor C2 is an example of a second capacitor and is connected between the inductor L4 and ground. That is, the capacitor C2 is connected in shunt to the path connecting the input terminal 140 and the output terminal 141. Specifically, one end of the capacitor C2 is connected to the inductor L4, and the other end of the capacitor C2 is connected to ground.

In an exemplary aspect, the switch SW2 is an example of a second switch and is connected between the input terminal 140 and the output terminal 141 without via the inductor L1 or L3. That is, the switch SW2 is connected in series to a path that bypasses the inductors L1 and L3 between the input terminal 140 and the output terminal 141. Specifically, one terminal of the switch SW2 is connected to a node N40 on a path connecting the input terminal 140 and the inductor L1, and the other terminal of the switch SW2 is connected to a node N45 on the path connecting the inductor L3 and the output terminal 141.

In FIG. 5, the node N43 to which the other terminal of the switch SW1 is connected is located between the node N42 to which the inductor L2 is connected and the inductor L1, but the positional relationship between the nodes N42 and N43 is not limited thereto. For example, the node N42 may be located between the node N43 and the inductor L1. Alternatively, for example, the position of the node N42 may be the same as the position of the node N43. The positional relationship between the nodes N44 and N45 is not limited to the relationship in FIG. 5.

The switch SW2 connected in this manner is switched between ON and OFF on the basis of a control signal S4, together with the switch SW1. Accordingly, the filter circuit 41 is configured to function as a variable band elimination filter. For example, ON/OFF control of the switches SW1 and SW2 implements the variable band elimination filter in the following manner.

TABLE 2

| | SW1 | SW2 |
|---|---|---|
| (1) No BEF | ON/OFF | ON |
| (2) BEF2 | ON | OFF |
| (3) BEF1 + BEF2 | OFF | OFF |

Closing of the switches SW1 and SW2 causes the inductor L2 and the capacitor C1 to be connected to the input terminal 140 without via the inductor L1 and causes the inductor L4 and the capacitor C2 to be connected to the input terminal 140 without via the inductor L3. Accordingly, the inductor L2 and the capacitor C1 do not function as a band elimination filter, and the inductor L4 and the capacitor C2 do not function as a band elimination filter (No BEF) in this exemplary aspect. At this time, the switch SW1 may be opened.

Closing of the switch SW1 and opening of the switch SW2 cause the inductor L2 and the capacitor C1 to be connected to the input terminal 140 without via the inductor L1 and cause the inductor L4 and the capacitor C2 to be connected to the input terminal 140 via the inductor L3. Accordingly, the inductor L4 and the capacitor C2 function as a band elimination filter, whereas the inductor L2 and the capacitor C1 do not function as a band elimination filter (BEF2) in this exemplary aspect.

Opening of the switches SW1 and SW2 causes the inductor L2 and the capacitor C1 to be connected to the input terminal 140 via the inductor L1 and causes the inductor L4 and the capacitor C2 to be connected to the input terminal 140 via the inductor L3. Accordingly, the inductor L2 and the capacitor C1 can be configured to function as a band elimination filter, and the inductor L4 and the capacitor C2 can be configured to function as a band elimination filter (BEF1+BEF2).

Such control of a variable band elimination filter can be performed on the basis of, for example, the channel band width and/or the frequency band of the RF signal RF_{A} as in the first aspect but is not limited thereto.

### [1.2.6 Circuit Configuration of Filter Circuit 42]

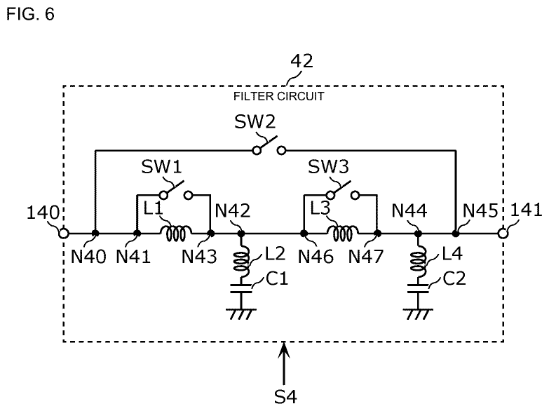

Next, the circuit configuration of the filter circuit 42 according to the third aspect of the present embodiment will be described with reference to FIG. 6.

As illustrated in FIG. 6, the filter circuit 42 includes inductors L1 to L4, capacitors C1 and C2, switches SW1 to SW3, an input terminal 140, and an output terminal 141.

In an exemplary aspect, the switch SW3 is an example of a third switch and is connected between the inductor L1 and the output terminal 141 without via the inductor L3. That is, the switch SW3 is connected in series to a path that bypasses the inductor L3 between the input terminal 140 and the output terminal 141. Specifically, one terminal of the switch SW3 is connected to a node N46 on a path connecting the inductors L1 and L3, and the other terminal of the switch SW3 is connected to a node N47 on a path connecting the inductor L3 and the output terminal 141.

In FIG. 6, the node N47 to which the other terminal of the switch SW3 is connected is located between the node N44 to which the inductor L4 is connected and the inductor L3, but the positional relationship between the nodes N44 and N47 is not limited thereto. For example, the node N44 may be located between the node N47 and the inductor L3. Alternatively, for example, the position of the node N44 may be the same as the position of the node N47. The positional relationship between the nodes N42 and N47 is not limited to the relationship in FIG. 6.

The switch SW3 connected in this manner is switched between ON and OFF on the basis of a control signal S4, together with the switches SW1 and SW2. Accordingly, the filter circuit 42 is configured to function as a variable band elimination filter. For example, ON/OFF control of the switches SW1 to SW3 implements the variable band elimination filter in the following manner.

TABLE 3

| | SW1 | SW2 | SW3 |
|---|---|---|---|
| (1) No BEF | ON/OFF | ON | ON/OFF |
| (2) BEF1 | OFF | OFF | ON |
| (3) BEF2 | ON | OFF | OFF |
| (4) BEF1 + BEF2 | OFF | OFF | OFF |

Closing of all the switches SW1 to SW3 causes the inductor L2 and the capacitor C1 to be connected to the input terminal 140 without via the inductor L1 and causes the inductor L4 and the capacitor C2 to be connected to the input terminal 140 without via the inductor L3. Accordingly, the inductor L2 and the capacitor C1 do not function as a band elimination filter, and the inductor L4 and the capacitor C2 do not function as a band elimination filter (No BEF) in this exemplary aspect. At this time, the switch SW1 and/or the switch SW3 may be opened.

Closing of the switch SW3 and opening of the switches SW1 and SW2 cause the inductor L2 and the capacitor C1 to be connected to the input terminal 140 via the inductor L1 and cause the inductor L4 and the capacitor C2 to be connected to the input terminal 140 without via the inductor L3. Accordingly, the inductor L2 and the capacitor C1 are configured to function as a band elimination filter, whereas the inductor L4 and the capacitor C2 do not function as a band elimination filter (BEF1) in this exemplary aspect.

Closing of the switch SW1 and opening of the switches SW2 and SW3 cause the inductor L2 and the capacitor C1 to be connected to the input terminal 140 without via the inductor L1 and cause the inductor L4 and the capacitor C2 to be connected to the input terminal 140 via the inductor L3. Accordingly, the inductor L4 and the capacitor C2 are configured to function as a band elimination filter, whereas the inductor L2 and the capacitor C1 do not function as a band elimination filter (BEF2) in this exemplary aspect.

Opening of all the switches SW1 to SW3 causes the inductor L2 and the capacitor C1 to be connected to the input terminal 140 via the inductor L1 and causes the inductor L4 and the capacitor C2 to be connected to the input terminal 140 via the inductor L3. Accordingly, the inductor L2 and the capacitor C1 are configured to function as a band elimination filter, and the inductor L4 and the capacitor C2 are configured to function as a band elimination filter (BEF1+BEF2) in this exemplary aspect.

Such control of a variable band elimination filter can be performed on the basis of, for example, the channel band width and/or the frequency band of the RF signal RF_{A} as in the first aspect but is not limited thereto.

### [1.2.7 Circuit Configuration of Filter Circuit 43]

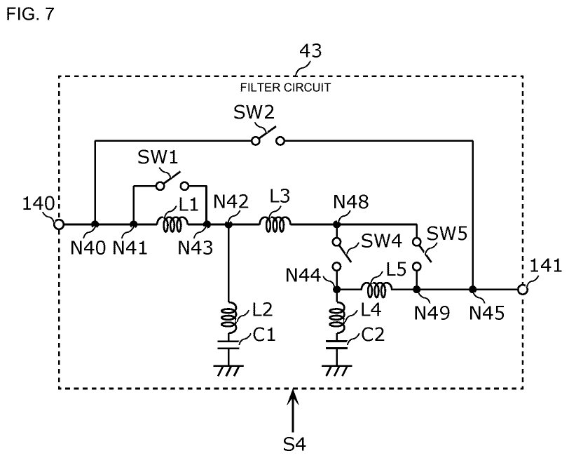

Next, the circuit configuration of the filter circuit 43 according to the fourth aspect of the present embodiment will be described with reference to FIG. 7.

As illustrated in FIG. 7, the filter circuit 43 includes inductors L1 to L5, capacitors C1 and C2, switches SW1, SW2, SW4, and SW5, an input terminal 140, and an output terminal 141.

In an exemplary aspect, the switch SW4 is an example of a fourth switch and is connected between the inductor L3 and the output terminal 141. That is, the switch SW4 is connected in series to a path connecting the input terminal 140 and the output terminal 141. Specifically, one terminal of the switch SW4 is connected to a node N48 on a path connecting the inductor L3 and the output terminal 141, and the other terminal of the switch SW4 is connected to a node N44 on a path connecting the inductors L4 and L5.

In an exemplary aspect, the switch SW5 is an example of a fifth switch and is connected between the inductor L3 and the output terminal 141 without via the switch SW4 or the inductor L5. That is, the switch SW5 is connected in series to the path connecting the input terminal 140 and the output terminal 141. Specifically, one terminal of the switch SW5 is connected to the node N48 on the path connecting the inductor L3 and the output terminal 141, and the other terminal of the switch SW5 is connected to a node N49 on a path connecting the inductor L5 and the output terminal 141.

In an exemplary aspect, the inductor L5 is an example of a fifth inductor and is connected between the switch SW4 and the output terminal 141. That is, the inductor L5 is connected in series to the path connecting the input terminal 140 and the output terminal 141 via the switch SW4. Furthermore, the inductor L5 is connected between the switch SW5 and the inductor L4. That is, the inductor L5 is connected in shunt to the path connecting the input terminal 140 and the output terminal 141 via the switch SW5. Specifically, one end of the inductor L5 is connected to the switch SW4 and the inductor L4, and the other end of the inductor L5 is connected to the switch SW5 and the output terminal 141.

The switches SW4 and SW5 connected in this manner are switched between ON and OFF on the basis of a control signal S4, together with the switches SW1 and SW2. Accordingly, the filter circuit 43 is configured to function as a variable band elimination filter. For example, ON/OFF control of the switches SW1, SW2, SW4, and SW5 implements the variable band elimination filter in the following manner.

TABLE 4

| | SW1 | SW2 | SW4 | SW5 |
|---|---|---|---|---|
| (1) No BEF | ON | ON | OFF | ON |
| (2) BEF2 | ON | OFF | ON | OFF |
| (3) BEF3 | ON | OFF | OFF | ON |
| (4) BEF1 + BEF2 | OFF | OFF | ON | OFF |
| (5) BEF1 + BEF3 | OFF | OFF | OFF | ON |

Closing of the switches SW1, SW2, and SW5 and opening of the switch SW4 cause the inductor L2 and the capacitor C1 to be connected to the input terminal 140 without via the inductor L1, and cause the inductor L4 and the capacitor C2 to be connected to the input terminal 140 without via the inductor L3. Accordingly, the inductor L2 and the capacitor C1 do not function as a band elimination filter, the inductor L4 and the capacitor C2 do not function as a band elimination filter, and the inductors L4 and L5 and the capacitor C2 do not function as a band elimination filter (No BEF) in this exemplary aspect.

Closing of the switches SW1 and SW4 and opening of the switches SW2 and SW5 cause the inductor L2 and the capacitor C1 to be connected to the input terminal 140 without via the inductor L1 and cause the inductor L4 and the capacitor C2 to be connected to the input terminal 140 via the inductor L3. Accordingly, the inductor L4 and the capacitor C2 can be configured to function as a band elimination filter, whereas the inductor L2 and the capacitor C1 do not function as a band elimination filter (BEF2) in the exemplary aspect.

Closing of the switches SW1 and SW5 and opening of the switches SW2 and SW4 cause the inductor L2 and the capacitor C1 to be connected to the input terminal 140 without via the inductor L1, and cause the inductors L4 and L5 and the capacitor C2 to be connected to the input terminal 140 via the inductor L3. Accordingly, the inductors L4 and L5 and the capacitor C2 can be configured to function as a band elimination filter, whereas the inductor L2 and the capacitor C1 do not function as a band elimination filter (BEF3) in this exemplary aspect.

Closing of the switch SW4 and opening of the switches SW1, SW2, and SW5 cause the inductor L2 and the capacitor C1 to be connected to the input terminal 140 via the inductor L1 and cause the inductor L4 and the capacitor C2 to be connected to the input terminal 140 via the inductor L3. Accordingly, the inductor L2 and the capacitor C1 can be configured to function as a band elimination filter, and the inductor L4 and the capacitor C2 can be configured to function as a band elimination filter (BEF1+BEF2) in this exemplary aspect.

Closing of the switch SW5 and opening of the switches SW1, SW2, and SW4 cause the inductor L2 and the capacitor C1 to be connected to the input terminal 140 via the inductor L1, and cause the inductors L4 and L5 and the capacitor C2 to be connected to the input terminal 140 via the inductor L3. Accordingly, the inductor L2 and the capacitor C1 can be configured to function as a band elimination filter, and the inductors L4 and L5 and the capacitor C2 can be configured to function as a band elimination filter (BEF1+BEF3) in this exemplary aspect.

Such control of a variable band elimination filter can be performed on the basis of, for example, the channel band width and/or the frequency band of the RF signal RF_{A} as in the first aspect but is not limited thereto.

### [1.2.8 Circuit Configuration of Digital Control Circuit 60]

Next, the circuit configuration of the digital control circuit 60 will be described. As illustrated in FIG. 8, the digital control circuit 60 includes a first controller 61, a second controller 62, capacitors C81 and C82, and control terminals 601 to 604.

The first controller 61 is configured to process source-synchronous digital control signals received from the RFIC 5 via the control terminals 601 and 602, thereby generating control signals S1, S2, and S4. The control signal S1 is a signal for controlling ON/OFF of the switches S61 to S63, S71, and S72 included in the pre-regulator circuit 10. The control signal S2 is a signal for controlling ON/OFF of the switches S11 to S14, S21 to S24, S31 to S34, and S41 to S44 included in the switched-capacitor circuit 20. The control signal S4 is a signal for controlling ON/OFF of the switches SW1 to SW5 included in the filter circuits 40 to 43.

The digital control signals processed by the first controller 61 are not limited to source-synchronous digital control signals. For example, the first controller 61 may process a clock-embedded digital control signal. The first controller 61 may generate a control signal for controlling the supply modulator 30.

In the present embodiment, one set of a clock signal and a data signal is used as digital control signals for the pre-regulator circuit 10, the switched-capacitor circuit 20, and the filter circuits 40 to 43, but the digital control signals are not limited thereto. For example, sets of a clock signal and a data signal may be individually used as digital control signals for the pre-regulator circuit 10, the switched-capacitor circuit 20, and the filter circuits 40 to 43.

The second controller 62 processes digital control logic/line (DCL) signals (DCL1 and DCL2) received from the RFIC 5 via the control terminals 603 and 604, thereby generating a control signal S3. The DCL signals (DCL1 and DCL2) are generated on the basis of an envelope signal or the like of an RF signal by the RFIC 5. The control signal S3 is a signal for controlling ON/OFF of the switches S51 to S54 included in the supply modulator 30.

The DCL signals (DCL1 and DCL2) are each a 1-bit signal. The voltages V1 to V4 are each represented by a combination of two 1-bit signals. For example, V1, V2, V3, and V4 are represented by “00”, “01”, “10”, and “11”, respectively. A gray code may be used to express a voltage level.

The capacitor C81 is connected between the first controller 61 and ground. For example, the capacitor C81 is connected between ground and a power supply line that supplies power to the first controller 61 and is configured to function as a bypass capacitor. The capacitor C82 is connected between the second controller 62 and ground.

In the present embodiment, two digitally controlled level (DCL) signals are used to control the supply modulator 30, but the number of digitally controlled level (DCL) signals is not limited thereto. For example, one or any number of three or more digitally controlled level (DCL) signals may be used in accordance with the number of voltage levels selectable by each supply modulator 30. The digital control signal used to control the supply modulator 30 is not limited to a digitally controlled level (DCL) signal.

### [1.3 Packaging Example of Tracker Circuit 1]

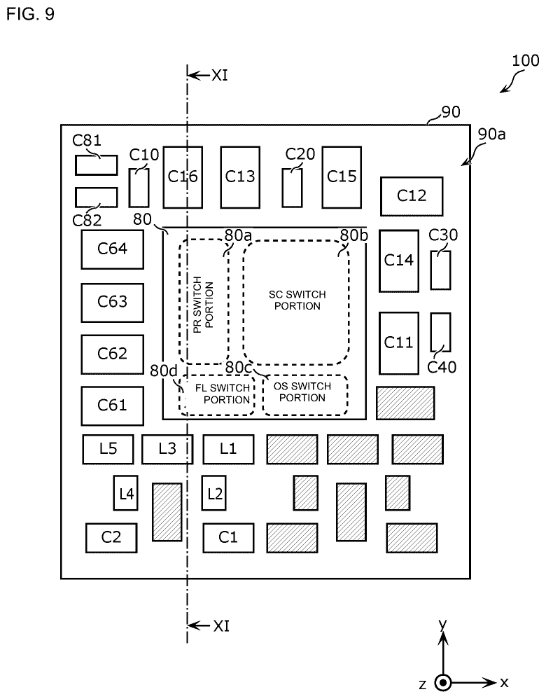

Next, a tracker module 100 will be described as a packaging example of the tracker circuit 1 having the above-described configuration, with reference to FIG. 9 to FIG. 11. A description will be given here of a packaging example of the tracker circuit 1 including the filter circuit 43. The tracker circuit 1 including any one of the filter circuits 40 to 42 may be packaged similarly to the tracker circuit 1 including the filter circuit 43.

In this packaging example, the power inductor L71 included in the pre-regulator circuit 10 is not disposed on or in a module laminate 90, but the disposition is not limited thereto. That is, the power inductor L71 may be disposed on or in the module laminate 90.

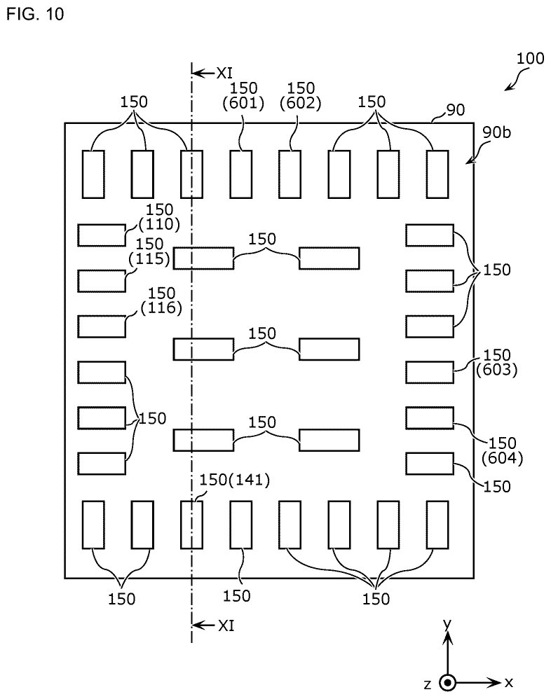

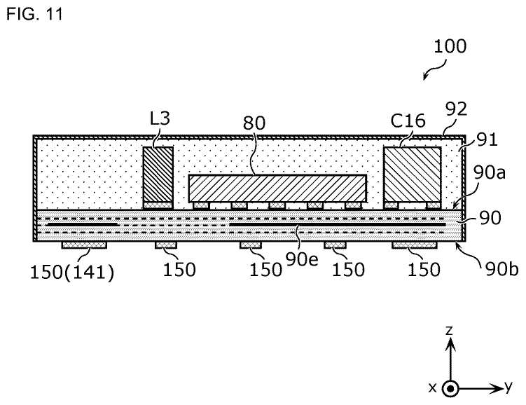

FIG. 9 is a plan view of the tracker module 100 according to the present embodiment. FIG. 10 is a plan view of the tracker module 100 according to the present embodiment, in which a main surface 90b of the module laminate 90 is seen through from the positive side of the z-axis. FIG. 11 is a sectional view of the tracker module 100 according to the present embodiment. The section of the tracker module 100 in FIG. 11 is a section taken along the XI-XI line in FIG. 9 and FIG. 10.

In FIG. 9 to FIG. 11, the illustration of some of wiring lines connecting a plurality of circuit components disposed on or in the module laminate 90 is omitted. In FIG. 9 and FIG. 10, the illustration of a resin member 91 covering the plurality of circuit components and a shield electrode layer 92 covering the surface of the resin member 91 is omitted. In FIG. 9, hatched blocks represent optional circuit components that can be omitted in certain exemplary aspects of the present disclosure.

As shown, the tracker module 100 includes the module laminate 90, the resin member 91, the shield electrode layer 92, and a plurality of external connection terminals 150, in addition to the plurality of circuit components including the active elements and passive elements included in the pre-regulator circuit 10, the switched-capacitor circuit 20, the supply modulator 30, the filter circuit 43, and the digital control circuit 60 illustrated in FIG. 9.

The module laminate 90 has a main surface 90a and the main surface 90b opposed to each other. A ground plane 90e and so forth are formed in the module laminate 90 and on the main surface 90a. In FIG. 9 and FIG. 10, the module laminate 90 has a rectangular shape in plan view, but the shape of the module laminate 90 is not limited thereto.

The module laminate 90 may be, but is not limited to, a low temperature co-fired ceramics (LTCC) substrate or a high temperature co-fired ceramics (HTCC) substrate having a multilayer structure of a plurality of dielectric layers, a component-embedded board, a substrate including a redistribution layer (RDL), a printed circuit board, or the like, for example.

On the main surface 90a, there are disposed an integrated circuit 80; the capacitors C1, C2, C10 to C16, C20, C30, C40, C61 to C64, C81, and C82; the inductors L1 to L5; and the resin member 91.

The integrated circuit 80 includes a PR switch portion 80a, an SC switch portion 80b, an OS switch portion 80c, and an FL switch portion 80d. The PR switch portion 80a includes the switches S61 to S63, S71, and S72. The SC switch portion 80b includes the switches S11 to S14, S21 to S24, S31 to S34, and S41 to S44. The OS switch portion 80c includes the switches S51 to S54. The FL switch portion 80d includes the switches SW1, SW2, SW4, and SW5.

In FIG. 9, the PR switch portion 80a, the SC switch portion 80b, the OS switch portion 80c, and the FL switch portion 80d are included in the single integrated circuit 80, but the configuration is not limited thereto. For example, the PR switch portion 80a and the SC switch portion 80b may be included in an integrated circuit, and the OS switch portion 80c and the FL switch portion 80d may be included in another integrated circuit. Alternatively, for example, the SC switch portion 80b, the OS switch portion 80c, and the FL switch portion 80d may be included in an integrated circuit, and the PR switch portion 80a may be included in another integrated circuit. Alternatively, the PR switch portion 80a, the OS switch portion 80c, and the FL switch portion 80d may be included in an integrated circuit, and the SC switch portion 80b may be included in another integrated circuit. Alternatively, for example, the PR switch portion 80a, the SC switch portion 80b, the OS switch portion 80c, and the FL switch portion 80d may be respectively included in four integrated circuits.

In FIG. 9, the integrated circuit 80 has a rectangular shape in plan view of the module laminate 90, but the shape of the integrated circuit 80 is not limited thereto.

In an exemplary aspect, the integrated circuit 80 can be formed by using, for example, complementary metal oxide semiconductor (CMOS), and specifically may be manufactured by a silicon on insulator (SOI) process. It is noted that the integrated circuit 80 is not limited to CMOS.

The capacitors C10 to C16, C20, C30, C40, C61 to C64, C81, and C82 are each mounted as a chip capacitor. In an exemplary aspect, the chip capacitor can be a surface mount device (SMD) forming a capacitor. However, it is noted that the plurality of capacitors that are mounted are not limited to chip capacitors. For example, some or all of the plurality of capacitors may be included in an integrated passive device (IPD) or may be included in the integrated circuit 80 in alternative aspects.

The inductors L1 to L5 are each mounted as a chip inductor. In an exemplary aspect, the chip inductor can be an SMD forming an inductor. The inductors L1 to L5 that are mounted are not limited to chip inductors. For example, some or all of the inductors L1 to L5 may be included in an IPD.

The plurality of capacitors and inductors disposed on the main surface 90a in this manner are grouped for each circuit and disposed around the integrated circuit 80.

Specifically, a group of the capacitors C61 to C64 included in the pre-regulator circuit 10 is disposed in a region on the main surface 90a sandwiched between a straight line along the left side of the integrated circuit 80 and a straight line along the left side of the module laminate 90 in plan view of the module laminate 90. Accordingly, a group of the circuit components included in the pre-regulator circuit 10 is disposed near the PR switch portion 80a in the integrated circuit 80.

A group of the capacitors C10 to C16, C20, C30, and C40 included in the switched-capacitor circuit 20 is disposed in a region on the main surface 90a sandwiched between a straight line along the upper side of the integrated circuit 80 and a straight line along the upper side of the module laminate 90, and a region on the main surface 90a sandwiched between a straight line along the right side of the integrated circuit 80 and a straight line along the right side of the module laminate 90, in plan view of the module laminate 90. Accordingly, a group of the circuit components included in the switched-capacitor circuit 20 is disposed near the SC switch portion 80b in the integrated circuit 80. That is, the SC switch portion 80b is disposed closer to the switched-capacitor circuit 20 than each of the PR switch portion 80a and the OS switch portion 80c.

A group of the capacitors C1 and C2 and the inductors L1 to L5 included in the filter circuit 43 is disposed in a region on the main surface 90a sandwiched between a straight line along the lower side of the integrated circuit 80 and a straight line along the lower side of the module laminate 90 in plan view of the module laminate 90. Accordingly, a group of the circuit components included in the filter circuit 43 is disposed near the FL switch portion 80d in the integrated circuit 80. That is, the FL switch portion 80d is disposed closer to the capacitors C1 and C2 and the inductors L1 to L5 of the filter circuit 43 than each of the PR switch portion 80a and the SC switch portion 80b.

In particular, in FIG. 9, the inductor L1 is disposed on the main surface 90a so as to be adjacent to the integrated circuit 80. The inductor L2 is disposed on the main surface 90a so as to be adjacent to the inductor L1. The capacitor C1 is disposed on the main surface 90a so as to be adjacent to the inductor L2.

Similarly, the inductor L3 is disposed on the main surface 90a so as to be adjacent to the integrated circuit 80. The inductor L4 is disposed on the main surface 90a so as to be adjacent to the inductor L3. The capacitor C2 is disposed on the main surface 90a so as to be adjacent to the inductor L4.

The plurality of external connection terminals 150 are disposed on the main surface 90b. At least one of the plurality of external connection terminals 150 is connected to the output terminal 141 illustrated in FIG. 7. The plurality of external connection terminals 150 are electrically connected to the plurality of electronic components disposed on the main surface 90a via via conductors or the like formed in the module laminate 90. The plurality of external connection terminals 150 may be, but are not limited to, copper electrodes. For example, the plurality of external connection terminals 150 may be solder electrodes.

The resin member 91 covers the main surface 90a and at least a part of the plurality of electronic components on the main surface 90a. Thus, the resin member 91 can ensure reliability, such as mechanical strength and moisture resistance, of the plurality of electronic components on the main surface 90a. It should be appreciated that the resin member 91 can be omitted from the tracker module 100 in an exemplary aspect.

In an exemplary aspect, the shield electrode layer 92 is a metal thin film formed by sputtering, for example. The shield electrode layer 92 is formed so as to cover the surfaces (upper surface and side surfaces) of the resin member 91. The shield electrode layer 92 is connected to ground and can be configured to suppress entry of external noise into the electronic components forming the tracker module 100 and interference of noise generated in the tracker module 100 with other modules or other devices. It should be appreciated that the shield electrode layer 92 need not necessarily be included in the tracker module 100 in an alternative aspect.

It is noted that the configuration of the tracker module 100 illustrated in FIG. 9 to FIG. 11 is illustrative and is not restrictive. For example, one or some of the capacitors and inductors disposed on the main surface 90a may be formed in the module laminate 90. In addition, one or some of the capacitors and inductors disposed on the main surface 90a can be omitted from the tracker module 100 in exemplary aspects, and thus will not be disposed on or in the module laminate 90.

### [1.4 Technical Effects]

As described above, the tracker circuit 1 according to the present embodiment includes the supply modulator 30 configured to selectively output at least one of a plurality of discrete voltages to the PA 2A, and the filter circuit 40, 41, 42, or 43 connected between the supply modulator 30 and the PA 2A. The filter circuit 40, 41, 42, or 43 includes the inductor L1 connected between the supply modulator 30 and the PA 2A, the capacitor C1 connected between ground and a path connecting the inductor L1 and the PA 2A, and the switch SW1 connected between the supply modulator 30 and the PA 2A without via the inductor L1.

From another point of view, the tracker circuit 1 according to the present embodiment includes the external connection terminal 150 (e.g., the output terminal 141) connected to the PA 2A, the supply modulator 30 configured to selectively output at least one of a plurality of discrete voltages to the external connection terminal 150, and the filter circuit 40 connected between the supply modulator 30 and the external connection terminal 150. The filter circuit 40 includes the inductor L1 connected between the supply modulator 30 and the external connection terminal 150, the capacitor C1 connected between ground and a path connecting the inductor L1 and the external connection terminal 150, and the switch SW1 connected between the supply modulator 30 and the external connection terminal 150. The switch SW1 has one terminal connected to one end of the inductor L1, and has the other terminal connected to the other end of the inductor L1.

Accordingly, connection and disconnection of the path that bypasses the inductor L1 can be switched therebetween by the switch SW1. The effect of the filter formed of the capacitor C1 (and the inductor L2) is derived by the inductor L1. Thus, ON/OFF switching of the filter formed of the capacitor C1 (and the inductor L2) can be implemented by the switch SW1. In this case, the switch SW1 is not connected between the capacitor C1 and a path (voltage supply path) connecting the supply modulator 30 and the external connection terminal 150 (the PA 2A). In other words, the switch SW1 is not connected in shunt to the voltage supply path. Thus, degradation of the Q value of the filter resulting from the switch SW1 can be suppressed, and noise included in the plurality of discrete voltages can be effectively attenuated.

In addition, for example, in the tracker circuit 1 according to the present embodiment, the filter circuit 40, 41, 42, or 43 may further include the inductor L2 connected between ground and the path connecting the inductor L1 and the external connection terminal 150 (the PA 2A), the inductor L2 being connected in series to the capacitor C1.

Accordingly, an LC series circuit including the capacitor C1 and the inductor L2 is connected between ground and the path connecting the supply modulator 30 and the external connection terminal 150 (the PA 2A). Thus, the characteristics of the filter can be improved, and noise included in the plurality of discrete voltages can be attenuated more effectively.

In addition, for example, in the tracker circuit 1 according to the present embodiment, the filter circuit 41, 42, or 43 may further include the inductor L3 connected between the inductor L1 and the PA 2A, the capacitor C2 connected between ground and a path connecting the inductor L3 and the PA 2A, and the switch SW2 connected between the supply modulator 30 and the PA 2A without via the inductor L1 or the inductor L3. The switch SW1 may be connected between the supply modulator 30 and the inductor L3 without via the inductor L1.

From another point of view, in the tracker circuit 1 according to the present embodiment, the filter circuit 41, 42, or 43 may further include the inductor L3 connected between the inductor L1 and the external connection terminal 150, the capacitor C2 connected between ground and a path connecting the inductor L3 and the external connection terminal 150, and the switch SW2 connected between the supply modulator 30 and the external connection terminal 150. The switch SW2 may have one terminal connected to a path connecting the supply modulator 30 and the inductor L1, and have the other terminal connected to the path connecting the inductor L3 and the external connection terminal 150.

Accordingly, connection and disconnection of the path that bypasses the inductors L1 and L3 can be switched therebetween by the switch SW2. The effect of the filter formed of the capacitor C1 (and the inductor L2) is derived by the inductor L1, and the effect of the filter formed of the capacitor C2 (and the inductor L4) is derived by the inductor L3. Thus, ON/OFF switching of the filter formed of the capacitor C1 (and the inductor L2), and the filter formed of the capacitor C2 (and the inductor L4) can be implemented by the switch SW2. In this case, the switch SW2 is not connected between the capacitor C1 or C2 and a path (voltage supply path) connecting the supply modulator 30 and the external connection terminal 150 (the PA 2A). In other words, the switch SW2 is not connected in shunt to the voltage supply path. Thus, degradation of the Q value of the filter resulting from the switch SW2 can be suppressed, and noise included in the plurality of discrete voltages can be effectively attenuated.

In addition, for example, in the tracker circuit 1 according to the present embodiment, the filter circuit 41, 42, or 43 may further include the inductor L4 connected between ground and the path connecting the inductor L3 and the external connection terminal 150 (the PA 2A), the inductor L4 being connected in series to the capacitor C2.

Accordingly, an LC series circuit including the capacitor C2 and the inductor L4 is connected between ground and the path connecting the supply modulator 30 and the external connection terminal 150 (the PA 2A). Thus, the characteristics of the filter can be improved, and noise included in the plurality of discrete voltages can be attenuated more effectively.

In addition, for example, in the tracker circuit 1 according to the present embodiment, the filter circuit 42 may further include the switch SW3 connected between the inductor L1 and the PA 2A without via the inductor L3.

From another point of view, in the tracker circuit 1 according to the present embodiment, the filter circuit 42 may further include the switch SW3 connected between the inductor L1 and the external connection terminal 150. The switch SW3 may have one terminal connected to one end of the inductor L3, and have the other terminal connected to the other end of the inductor L3.

Accordingly, connection and disconnection of the path that bypasses the inductor L3 can be switched therebetween by the switch SW3. The effect of the filter formed of the capacitor C2 (and the inductor L4) is derived by the inductor L3. Thus, ON/OFF switching of the filter formed of the capacitor C2 (and the inductor L4) can be implemented by the switch SW3. In this case, the switch SW3 is not connected between the capacitor C2 and a path (voltage supply path) connecting the supply modulator 30 and the external connection terminal 150 (the PA 2A). In other words, the switch SW3 is not connected in shunt to the voltage supply path. Thus, degradation of the Q value of the filter resulting from the switch SW3 can be suppressed, and noise included in the plurality of discrete voltages can be effectively attenuated.

In addition, for example, in the tracker circuit 1 according to the present embodiment, the filter circuit 43 may further include the switch SW4 connected between the inductor L3 and the PA 2A, the inductor L5 connected between the switch SW4 and the PA 2A, and the switch SW5 connected between the inductor L3 and the PA 2A without via the switch SW4 or the inductor L5. The capacitor C2 may be connected between ground and a path connecting the switch SW4 and the inductor L5.

From another point of view, in the tracker circuit 1 according to the present embodiment, the filter circuit 43 may further include the switch SW4 connected between the inductor L3 and the external connection terminal 150, the inductor L5 connected between the switch SW4 and the external connection terminal 150, and the switch SW5 connected between the inductor L3 and the external connection terminal 150. The switch SW4 may have one terminal connected to the inductor L3, and have the other terminal connected to one end of the inductor L5. The switch SW5 may have one terminal connected to the inductor L3, and have the other terminal connected to the other end of the inductor L5. The capacitor C2 may be connected between ground and a path connecting the switch SW4 and the inductor L5.

Accordingly, the switches SW4 and SW5 enable shunt connection to the power supply path to be switched between an LC series circuit including the inductor L4 and the capacitor C2 and an LC series circuit including the inductors L4 and L5 and the capacitor C2. In this case, the inductor L4 and the capacitor C2 can be shared between the two LC series circuits, and the number of circuit elements of the filter circuit 43 can be reduced.

In addition, for example, in the tracker circuit 1 according to the present embodiment, the switch SW1 and the supply modulator 30 may be included in the single integrated circuit 80 disposed on or in the module laminate 90.

Accordingly, a reduced size of the tracker module 100 including the tracker circuit 1 can be realized. Furthermore, the wiring length between the supply modulator 30 and any one of the filter circuits 40 to 43 can be shortened, and resistance loss resulting from the wiring can be reduced.

In addition, for example, in the tracker circuit 1 according to the present embodiment, the inductor L1 may be disposed on or in the module laminate 90 so as to be adjacent to the integrated circuit 80.

Accordingly, the wiring length between the inductor L1 and the switch SW1 can be shortened, and resistance loss resulting from the wiring can be reduced.

In addition, for example, in the tracker circuit 1 according to the present embodiment, at least one of the capacitor C1 or the inductor L2 may be disposed on or in the module laminate 90 so as to be adjacent to the inductor L1.

Accordingly, the wiring length between the inductor L1 and the inductor L2 or the capacitor C1 can be shortened, and the characteristics of the filter can be improved.

### Second Exemplary Embodiment

Next, a second exemplary embodiment will be described. It is noted that the present embodiment is different from the first embodiment mainly in that each of two supply modulators can be configured to supply a plurality of discrete voltages to a corresponding one of two PAs. Hereinafter, the second embodiment will be described with a focus on differences from the first exemplary embodiment with reference to the drawings.

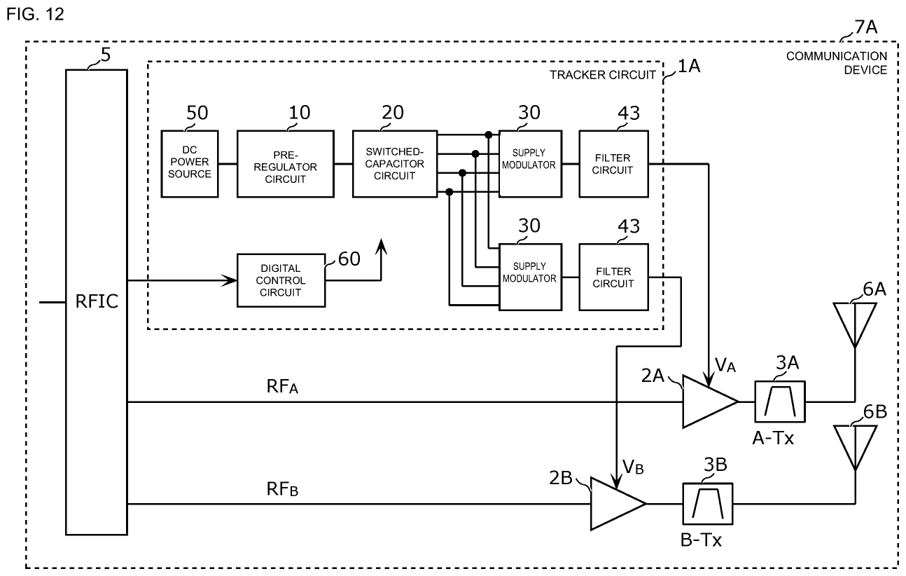

The circuit configuration of a communication device 7A and a tracker circuit 1A according to the present embodiment will be described with reference to FIG. 12. FIG. 12 is a circuit configuration diagram of the communication device 7A according to the present embodiment.

FIG. 12 illustrates an exemplary circuit configuration. The communication device 7A and the tracker circuit 1A may be packaged by using any of a wide variety of circuit packaging methods and circuit techniques. Thus, the description of the communication device 7A and the tracker circuit 1A provided below should not be so limited according to the exemplary aspects.

### [2.1 Circuit Configuration of Communication Device 7A]

The communication device 7A includes the tracker circuit 1A, PAs 2A and 2B, filters 3A and 3B, an RFIC 5, and antennas 6A and 6B.

The tracker circuit 1A is configured to supply a plurality of discrete voltages V_{A} to the PA 2A and supplying a plurality of discrete voltages V_{B} to the PA 2B, on the basis of a tracking mode. As illustrated in FIG. 12, the tracker circuit 1A includes a pre-regulator circuit 10, a switched-capacitor circuit 20, two supply modulators 30, two filter circuits 43, a DC power source 50, and a digital control circuit 60. The number of supply modulators 30 and the number of filter circuits 43 included in the tracker circuit 1A are not limited to two. The number of supply modulators 30 and the number of filter circuits 43 may be three or more.

The PA 2B is connected between the RFIC 5 and the filter 3B. The PA 2B is further connected to the tracker circuit 1A. The PA 2B is configured to amplify an RF signal RFB of band B received from the RFIC 5, by using the plurality of discrete voltages V_{B} received from the tracker circuit 1A.

The filter 3B is connected between the PA 2B and the antenna 6B. The filter 3B is a band pass filter having a pass band including band B. Like band A, band B is a frequency band for a communication system constructed by using RAT and is predefined by a standardizing body or the like.

The antenna 6B outputs a transmission signal of band B received from the PA 2B through the filter 3B. It should be appreciated that the antenna 6B can be omitted from the communication device 7A in an exemplary aspect.

### [2.2 Technical Effects]

As described above, the tracker circuit 1A according to the present embodiment may include the two supply modulators 30 and the two filter circuits 43.

Accordingly, different discrete voltages can be simultaneously supplied to the two PAs 2A and 2B. In this case, the pre-regulator circuit 10 and the switched-capacitor circuit 20 can be shared between the two PAs 2A and 2B, which contributes to a reduced number of components and a reduced size of the communication device 7A.

### Third Exemplary Embodiment

Next, a third exemplary embodiment will be described. It is noted that the present embodiment is different from the second embodiment mainly in that two supply modulators are configured to supply a plurality of discrete voltages to each of three PAs. Hereinafter, the third exemplary embodiment will be described with a focus on differences from the second exemplary embodiment with reference to the drawings.

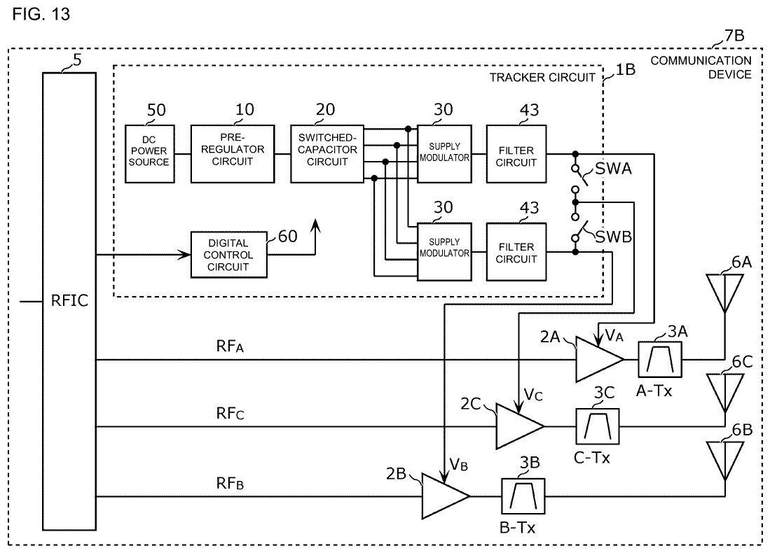

The circuit configuration of a communication device 7B and a tracker circuit 1B according to the present embodiment will be described with reference to FIG. 13. FIG. 13 is a circuit configuration diagram of the communication device 7B according to the present embodiment.

FIG. 13 illustrates an exemplary circuit configuration. The communication device 7B and the tracker circuit 1B may be packaged by using any of a wide variety of circuit packaging methods and circuit techniques. Thus, the description of the communication device 7B and the tracker circuit 1B provided below should not be so limited according to the exemplary aspects.

### [3.1 Circuit Configuration of Communication Device 7B]

The communication device 7B includes the tracker circuit 1B, PAs 2A to 2C, filters 3A to 3C, an RFIC 5, and antennas 6A to 6C.

The tracker circuit 1B is configured to supply a plurality of discrete voltages V_{A} to the PA 2A, supplying a plurality of discrete voltages V_{B} to the PA 2B, and supplying a plurality of discrete voltages V_{C} to the PA 2C, on the basis of a tracking mode. As illustrated in FIG. 13, the tracker circuit 1B includes a pre-regulator circuit 10, a switched-capacitor circuit 20, two supply modulators 30, two filter circuits 43, a DC power source 50, a digital control circuit 60, and switches SWA and SWB.

The switch SWA is connected between one of the two filter circuits 43 and the PA 2C. That is, the switch SWA is connected in series to a path connecting one of the two filter circuits 43 and the PA 2C. Specifically, one terminal of the switch SWA is connected to one of the two filter circuits 43, and the other terminal of the switch SWA is connected to the PA 2C. The switch SWA is configured to switch between connection and disconnection between one of the two filter circuits 43 and the PA 2C.

The switch SWB is connected between the other of the two filter circuits 43 and the PA 2C. That is, the switch SWB is connected in series to a path connecting the other of the two filter circuits 43 and the PA 2C. Specifically, one terminal of the switch SWB is connected to the other of the two filter circuits 43, and the other terminal of the switch SWB is connected to the PA 2C. The switch SWB can be configured to switch between connection and disconnection between the other of the two filter circuits 43 and the PA 2C.

The PA 2C is connected between the RFIC 5 and the filter 3C. The PA 2C is further connected to the tracker circuit 1B. The PA 2C is configured to amplify an RF signal RF_{C} of band C received from the RFIC 5, by using the plurality of discrete voltages V_{C} received from the tracker circuit 1B.

The filter 3C is connected between the PA 2C and the antenna 6C. The filter 3C is a band pass filter having a pass band including band C. Like bands A and B, band C is a frequency band for a communication system constructed by using RAT and is predefined by a standardizing body or the like.

The antenna 6C outputs a transmission signal of band C received from the PA 2C through the filter 3C. It should be appreciated that the antenna 6C can be omitted from the communication device 7B in an exemplary aspect.

### [3.2 Technical Effects]

As described above, the tracker circuit 1B according to the present embodiment may include the switch SWA connected between one of the two filter circuits 43 and the PA 2C, and the switch SWB connected between the other of the two filter circuits 43 and the PA 2C.

Accordingly, a combination of the supply modulator 30 and the filter circuit 43 configured to supply the plurality of discrete voltages V_{C} to the PA 2C can be switched. Thus, a combination of two PAs to be simultaneously supplied with different discrete voltages can be switched. For example, opening of the switch SWA and closing of the switch SWB make it possible to simultaneously supply different discrete voltages to the PAs 2A and 2C. For example, closing of the switch SWA and opening of the switch SWB make it possible to simultaneously supply different discrete voltages to the PAs 2B and 2C. For example, opening of the switches SWA and SWB makes it possible to simultaneously supply different discrete voltages to the PAs 2A and 2B.

### Fourth Exemplary Embodiment

Next, a fourth exemplary embodiment will be described. It is noted that the present embodiment is different from the first embodiment mainly in that one supply modulator is configured to supply a plurality of discrete voltages to each of two PAs. Hereinafter, the fourth exemplary embodiment will be described with a focus on differences from the first exemplary embodiment with reference to the drawings.

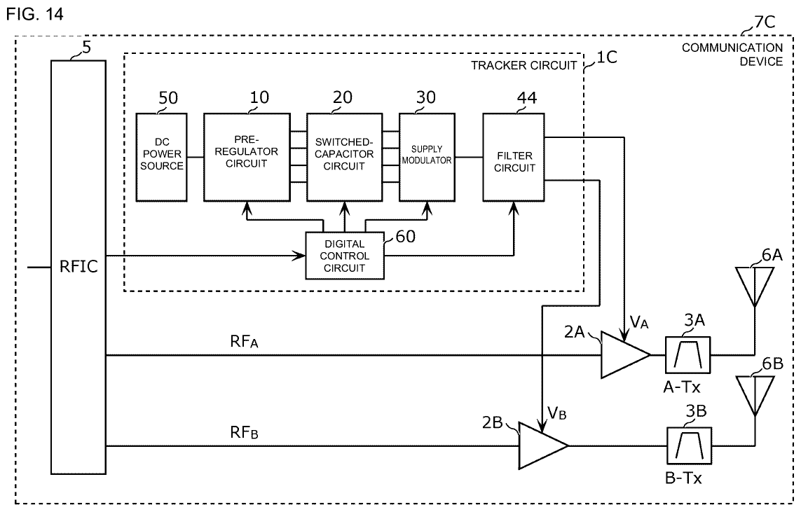

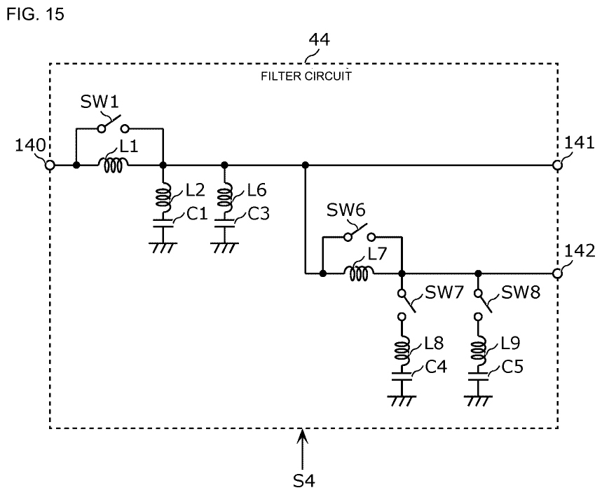

The circuit configuration of a communication device 7C and a tracker circuit 1C according to the present embodiment will be described with reference to FIG. 14 and FIG. 15. FIG. 14 is a circuit configuration diagram of the communication device 7C according to the present embodiment. FIG. 15 is a circuit configuration diagram of a filter circuit 44 according to the present embodiment.

FIG. 14 and FIG. 15 each illustrate an exemplary circuit configuration. The communication device 7C and the tracker circuit 1C may be packaged by using any of a wide variety of circuit packaging methods and circuit techniques. Thus, the description of the communication device 7C and the tracker circuit 1C provided below should not be so limited according to the exemplary aspects.

### [4.1 Circuit Configuration of Communication Device 7C]

The communication device 7C includes the tracker circuit 1C, PAs 2A and 2B, filters 3A and 3B, an RFIC 5, and antennas 6A and 6B.

The tracker circuit 1C is configured to supply a plurality of discrete voltages V_{A} to the PA 2A and supplying a plurality of discrete voltages V_{B} to the PA 2B, on the basis of a tracking mode. As illustrated in FIG. 14, the tracker circuit 1C includes a pre-regulator circuit 10, a switched-capacitor circuit 20, a supply modulator 30, the filter circuit 44, a DC power source 50, and a digital control circuit 60.

### [4.2 Circuit Configuration of Filter Circuit 44]

Next, the circuit configuration of the filter circuit 44 according to the present embodiment will be described with reference to FIG. 15.

As illustrated in FIG. 15, the filter circuit 44 includes inductors L1, L2, and L6 to L9, capacitors C1 and C3 to C5, switches SW1 and SW6 to SW8, an input terminal 140, and output terminals 141 and 142.

The output terminal 141 is an external connection terminal of the tracker circuit 1C and is connected to the PA 2A outside the tracker circuit 1C. The output terminal 141 is a terminal configured to supply the plurality of discrete voltages V_{A} that have passed through the filter circuit 44 to the PA 2A.

The output terminal 142 is an external connection terminal of the tracker circuit 1C and is connected to the PA 2B outside the tracker circuit 1C. The output terminal 142 is a terminal configured to supply the plurality of discrete voltages V_{B} that have passed through the filter circuit 44 to the PA 2B.

In an exemplary aspect, the inductor L1 is an example of a first inductor and is connected between the input terminal 140 and the output terminals 141 and 142. That is, the inductor L1 is connected in series to a path connecting the input terminal 140 and the output terminals 141 and 142. Specifically, one end of the inductor L1 is connected to the input terminal 140, and the other end of the inductor L1 is connected to the output terminals 141 and 142.

In an exemplary aspect, the inductor L2 is an example of a second inductor and is connected between ground and a path connecting the inductor L1 and the output terminals 141 and 142. That is, the inductor L2 is connected in shunt to the path connecting the input terminal 140 and the output terminals 141 and 142. Specifically, one end of the inductor L2 is connected to the path connecting the inductor L1 and the output terminals 141 and 142, and the other end of the inductor L2 is connected to ground via the capacitor C1.

In an exemplary aspect, the capacitor C1 is an example of a first capacitor and is connected between the inductor L2 and ground. That is, the capacitor C1 is connected in shunt to the path connecting the input terminal 140 and the output terminals 141 and 142. Specifically, one end of the capacitor C1 is connected to the inductor L2, and the other end of the capacitor C1 is connected to ground.

In an exemplary aspect, the switch SW1 is an example of a first switch and is connected between the input terminal 140 and the output terminals 141 and 142 without via the inductor L1. That is, the switch SW1 is connected in series to a path that bypasses the inductor L1 between the input terminal 140 and the output terminals 141 and 142. Specifically, one terminal of the switch SW1 is connected to a path connecting the input terminal 140 and the inductor L1, and the other terminal of the switch SW1 is connected to the path connecting the inductor L1 and the output terminals 141 and 142.

The inductor L6 is connected between ground and the path connecting the inductor L1 and the output terminals 141 and 142. That is, the inductor L6 is connected in shunt to the path connecting the input terminal 140 and the output terminals 141 and 142. Specifically, one end of the inductor L6 is connected to a path connecting the inductor L1 and the output terminal 141, and the other end of the inductor L6 is connected to ground via the capacitor C3.

The capacitor C3 is connected between the inductor L6 and ground. That is, the capacitor C3 is connected in shunt to the path connecting the input terminal 140 and the output terminals 141 and 142. Specifically, one end of the capacitor C3 is connected to the inductor L6, and the other end of the capacitor C3 is connected to ground.

The inductor L7 is connected between the inductor L1 and the output terminal 142. That is, the inductor L7 is connected in series to a path connecting the input terminal 140 and the output terminal 142. Specifically, one end of the inductor L7 is connected to the inductor L1, and the other end of the inductor L7 is connected to the output terminal 142.

The switch SW6 is connected between the inductor L1 and the output terminal 142 without via the inductor L7. That is, the switch SW6 is connected in series to a path that bypasses the inductor L7 between the input terminal 140 and the output terminal 142. Specifically, one terminal of the switch SW6 is connected to a path connecting the inductors L1 and L7, and the other terminal of the switch SW6 is connected to a path connecting the inductor L7 and the output terminal 142.

The switch SW7 is connected between ground and the path connecting the inductor L7 and the output terminal 142. That is, the switch SW7 is connected in shunt to the path connecting the input terminal 140 and the output terminal 142. Specifically, one terminal of the switch SW7 is connected to the path connecting the inductor L7 and the output terminal 142, and the other terminal of the switch SW7 is connected to ground via the inductor L8 and the capacitor C4.

The inductor L8 is connected between ground and the path connecting the inductor L7 and the output terminal 142 via the switch SW7. That is, the inductor L8 is connectable in shunt to the path connecting the input terminal 140 and the output terminal 142. Specifically, one end of the inductor L8 is connected to the switch SW7, and the other end of the inductor L8 is connected to ground via the capacitor C4.

The capacitor C4 is connected between the inductor L8 and ground. That is, the capacitor C4 is connectable in shunt to the path connecting the input terminal 140 and the output terminal 142. Specifically, one end of the capacitor C4 is connected to the inductor L8, and the other end of the capacitor C4 is connected to ground.

The switch SW8 is connected between ground and the path connecting the inductor L7 and the output terminal 142. That is, the switch SW8 is connected in shunt to the path connecting the input terminal 140 and the output terminal 142. Specifically, one terminal of the switch SW8 is connected to the path connecting the inductor L7 and the output terminal 142, and the other terminal of the switch SW8 is connected to ground via the inductor L9 and the capacitor C5.

The inductor L9 is connected between ground and the path connecting the inductor L7 and the output terminal 142 via the switch SW8. That is, the inductor L9 is connectable in shunt to the path connecting the input terminal 140 and the output terminal 142. Specifically, one end of the inductor L9 is connected to the switch SW8, and the other end of the inductor L9 is connected to ground via the capacitor C5.

The capacitor C5 is connected between the inductor L9 and ground. That is, the capacitor C5 is connectable in shunt to the path connecting the input terminal 140 and the output terminal 142. Specifically, one end of the capacitor C5 is connected to the inductor L9, and the other end of the capacitor C5 is connected to ground.

### [4.3 Technical Effects]

As described above, in the tracker circuit 1C according to the present embodiment, the switch SW7 may be connected between the voltage supply path and the LC series circuit including the inductor L8 and the capacitor C4, and the switch SW8 may be connected between the voltage supply path and the LC series circuit including the inductor L9 and the capacitor C5.

Also in this case, connection and disconnection of the path that bypasses the inductor L1 can be switched therebetween by the switch SW1, and effects similar to those of the above-described embodiments can be obtained.

### Additional Exemplary Embodiments

The tracker circuit according to the exemplary aspects of the present disclosure has been described above on the basis of the embodiments. It is noted that the exemplary tracker circuit is not limited to the above embodiments. Additional exemplary embodiments can be implemented by combining any constituent elements in the above embodiments, modifications obtained by applying various changes conceived by those skilled in the art to the above embodiments without departing from the gist of the present invention, and various devices including the above-described tracker circuit can also be included.

For example, in the circuit configurations of the various circuits according to the above embodiments, another circuit element, wiring line, and the like may be inserted between individual circuit elements and paths connecting signal paths disclosed in the drawings. For example, an impedance matching circuit may be inserted between the PA 2A and the filter 3A in an exemplary aspect.

In the above embodiments, a plurality of discrete voltages are supplied from the switched-capacitor circuit to the supply modulator, but the exemplary aspects are is not so limited. For example, a plurality of voltages may each be supplied from one of a plurality of DC-DC converters. In a case where the voltage levels of the plurality of discrete voltages are equally spaced, a switched-capacitor circuit can be used in an exemplary aspect, which is effective in reducing the size of the tracker module.

In the above embodiments, four discrete voltages are supplied to a PA, but it is noted that the number of discrete voltages is not limited to four. For example, when the plurality of discrete voltages includes at least a voltage corresponding to maximum output power and a voltage corresponding to output power having the highest occurrence frequency, power-added efficiency can be improved.

In the first embodiment, the plurality of circuit components of the tracker circuit 1 are disposed on the main surface 90a of the module laminate 90. Alternatively, the circuit components may be disposed on both the main surfaces 90a and 90b. In this case, for example, the integrated circuit 80 may be disposed on the main surface 90b.

The exemplary embodiments of the present disclosure can be widely used, as a tracker circuit for supplying a voltage to a power amplifier, in communication devices such as mobile phones.

### REFERENCE SIGNS LIST

1, 1A, 1B, 1C tracker circuit
2A, 2B, 2C power amplifier
3A, 3B, 3C filter
5 RFIC
6A, 6B, 6C antenna
7, 7A, 7B, 7C communication device
10 pre-regulator circuit
20 switched-capacitor circuit
30 supply modulator
40, 41, 42, 43, 44 filter circuit
50 DC power source
60 digital control circuit
61 first controller
62 second controller
80 integrated circuit
80a PR switch portion
80b SC switch portion
80c OS switch portion
80d FL switch portion
90 module laminate
90a, 90b main surface
90e ground plane
91 resin member
92 shield electrode layer
100 tracker module
110, 131, 132, 133, 134, 140 input terminal
111, 112, 113, 114, 130, 141, 142 output terminal
115, 116 inductor connection terminal
150 external connection terminal
601, 602, 603, 604 control terminal

1. A tracker circuit comprising:
a supply modulator configured to selectively output at least one voltage of a plurality of discrete voltages to a power amplifier; and
a filter circuit connected between the supply modulator and the power amplifier, the filter circuit including:
a first inductor connected between the supply modulator and the power amplifier,
a first capacitor connected between ground and a path connecting the first inductor to the power amplifier, and
a first switch connected between the supply modulator and the power amplifier without the first inductor connected therebetween.

2. The tracker circuit according to claim 1, wherein the filter circuit further includes a second inductor connected between ground and the path connecting the first inductor to the power amplifier, the second inductor being connected in series to the first capacitor.

3. The tracker circuit according to claim 1, wherein the filter circuit further includes:
a third inductor connected between the first inductor and the power amplifier,
a second capacitor connected between ground and a path connecting the third inductor to the power amplifier, and
a second switch connected between the supply modulator and the power amplifier without the first inductor or the third inductor connected therebetween,
wherein the first switch is connected between the supply modulator and the third inductor without the first inductor connected therebetween.

4. The tracker circuit according to claim 3, wherein the filter circuit further includes a fourth inductor connected between ground and the path connecting the third inductor to the power amplifier, the fourth inductor being connected in series to the second capacitor.

5. The tracker circuit according to claim 3, wherein the filter circuit further includes a third switch connected between the first inductor and the power amplifier without the third inductor connected therebetween.

6. The tracker circuit according to claim 3, wherein the filter circuit further includes:
a fourth switch connected between the third inductor and the power amplifier,
a fifth inductor connected between the fourth switch and the power amplifier, and
a fifth switch connected between the third inductor and the power amplifier without the fourth switch or the fifth inductor connected therebetween,
wherein the second capacitor is connected between ground and a path connecting the fourth switch to the fifth inductor.

7. The tracker circuit according to claim 1, further comprising a single integrated circuit that includes the first switch and the supply modulator, the single integrated circuit being disposed on or in a module laminate.

8. The tracker circuit according to claim 7, wherein the first inductor is disposed on or in the module laminate to be adjacent to the single integrated circuit.

9. The tracker circuit according to claim 2, further comprising a single integrated circuit that includes the first switch and the supply modulator, the single integrated circuit being disposed on or in a module laminate.

10. The tracker circuit according to claim 9, wherein the first inductor is disposed on or in the module laminate to be adjacent to the single integrated circuit.

11. The tracker circuit according to claim 10, wherein at least one of the first capacitor or the second inductor is on or in the module laminate to be adjacent to the first inductor.

12. A tracker circuit comprising:
an external connection terminal connected to a power amplifier;
a supply modulator configured to selectively output at least one voltage of a plurality of discrete voltages to the external connection terminal; and
a filter circuit connected between the supply modulator and the external connection terminal, the filter circuit including:
a first inductor connected between the supply modulator and the external connection terminal,
a first capacitor connected between ground and a path connecting the first inductor to the external connection terminal, and
a first switch connected between the supply modulator and the external connection terminal,
wherein the first switch has a first terminal connected to a first end of the first inductor, and has a second terminal connected to a second end of the first inductor.

13. The tracker circuit according to claim 12, wherein the filter circuit further includes a second inductor connected between ground and the path connecting the first inductor to the external connection terminal, the second inductor being connected in series to the first capacitor.

14. The tracker circuit according to claim 12, wherein the filter circuit further includes:
a third inductor connected between the first inductor and the external connection terminal,
a second capacitor connected between ground and a path connecting the third inductor to the external connection terminal, and
a second switch connected between the supply modulator and the external connection terminal,
wherein the second switch has a first terminal connected to a path that connects the supply modulator to the first inductor, and has a second terminal connected to the path that connects the third inductor to the external connection terminal.

15. The tracker circuit according to claim 14, wherein the filter circuit further includes a fourth inductor connected between ground and the path that connects the third inductor to the external connection terminal, the fourth inductor being connected in series to the second capacitor.

16. The tracker circuit according to claim 14, wherein:
the filter circuit further includes a third switch connected between the first inductor and the external connection terminal, and
the third switch has a first terminal connected to a first end of the third inductor, and has a second terminal connected to a second end of the third inductor.

17. The tracker circuit according to claim 14, wherein the filter circuit further includes:
a fourth switch connected between the third inductor and the external connection terminal,
a fifth inductor connected between the fourth switch and the external connection terminal, and
a fifth switch connected between the third inductor and the external connection terminal,
wherein the fourth switch has a first terminal connected to the third inductor, and has a second terminal connected to a first end of the fifth inductor,
wherein the fifth switch has a first terminal connected to the third inductor, and has a second terminal connected to a second end of the fifth inductor, and
wherein the second capacitor is connected between ground and a path that connects the fourth switch to the fifth inductor.

18. The tracker circuit according to claim 12, further comprising a single integrated circuit that includes the first switch and the supply modulator, the single integrated circuit being disposed on or in a module laminate.

19. The tracker circuit according to claim 18, wherein the first inductor is disposed on or in the module laminate to be adjacent to the single integrated circuit.

20. The tracker circuit according to claim 13, wherein:
the first switch and the supply modulator are included in a single integrated circuit disposed on or in a module laminate,
the first inductor is disposed on or in the module laminate to be adjacent to the integrated circuit, and
at least one of the first capacitor or the second inductor is disposed on or in the module laminate to be adjacent to the first inductor.
